(19) United States
(12) Patent Application Publication
(10) Pub. No.: US 2025/0210566 A1
(43) Pub. Date: Jun. 26, 2025

(54) SEMICONDUCTOR PACKAGE

(71) Applicant: Samsung Electronics Co., Ltd., Suwon-si (KR)

(72) Inventors: Sungmin Moon, Suwon-si (KR); PYOUNGWAN KIM, Suwon-si (KR)

(21) Appl. No.: 18/751,638

(22) Filed: Jun. 24, 2024

(30) Foreign Application Priority Data
Dec. 21, 2023 (KR) 10-2023-0188321

(51) Int. Cl. H01L 23/00; H01L 23/31; H01L 23/49; H01L 23/498

(52) U.S. Cl. CPC H01L 24/24; H01L 23/3107; H01L 23/49; H01L 23/49822; H01L 23/49816; H01L 24/16; H01L 24/32; H01L 24/73; H01L 2224/16225; H01L 2224/2405; H01L 2224/32225; H01L 2224/73204

(57) ABSTRACT

A semiconductor package includes a lower package substrate, a semiconductor chip mounted on the lower package substrate, a molding member positioned on the lower package substrate and covering at least a portion of the semiconductor chip, and a conductive post positioned within the molding member. The molding member and the conductive post define a trench including a first inner surface recessed toward the lower package substrate from an upper surface of the molding member and a second inner surface corresponding to a side surface of the conductive post. The side surface of the conductive post extends beyond the first inner surface of the trench in a direction away from the lower package substrate. The first inner surface of the molding member includes a first curved surface connecting the upper surface of the molding member to the side surface of the conductive post.

### CROSS-REFERENCE TO RELATED APPLICATION

This application claims priority to and the benefit of Korean Patent Application No. 10-2023-0188321 filed in the Korean Intellectual Property Office on Dec. 21, 2023, the entire contents of which are herein incorporated by reference.

### BACKGROUND OF THE DISCLOSURE

### 1. Field

The present disclosure relates to a semiconductor package.

### 2. Description of the Related Art

In a semiconductor industry, as a demand for high-capacity, thinner, and downsized semiconductor devices and electronic products using them increases, various package technologies of such semiconductor devices are emerging. For example, in accordance with a recent trend toward higher performance and compactness of the electronic devices, a package-on-package (POP) technology is being developed in a semiconductor packaging field.

In the package-on-package technology, two or more semiconductor packages are stacked, so it is desirable to prevent cracks or a delamination from occurring in a region where wires and insulating layers included in the semiconductor package contact each other.

### SUMMARY

The embodiments are intended to provide semiconductor packages with improved reliability and productivity.

According to an aspect of the present disclosure, a semiconductor package includes a lower package substrate including a lower redistribution insulation layer and a lower redistribution pattern positioned within the lower redistribution insulation layer, a semiconductor chip mounted on the lower package substrate, a connection terminal positioned between the lower package substrate and the semiconductor chip, and connecting the semiconductor chip to the lower package substrate, a molding member positioned on the lower package substrate and covering at least a portion of the semiconductor chip, and a conductive post positioned within the molding member and connected to the lower redistribution pattern. The molding member and the conductive post define a trench. The trench includes a first inner surface recessed toward the lower package substrate from an upper surface of the molding member and a second inner surface corresponding to a side surface of the conductive post. The side surface of the conductive post extends beyond the first inner surface of the trench in a direction away from the lower package substrate. The first inner surface of the molding member includes a first curved surface connecting the upper surface of the molding member to the side surface of the conductive post.

According to an aspect of the present disclosure, a semiconductor package includes a lower package substrate including a lower redistribution insulation layer and a lower redistribution pattern positioned within the lower redistribution insulation layer, a semiconductor chip mounted on the lower package substrate, a connection terminal positioned between the lower package substrate and the semiconductor chip, and connecting the semiconductor chip to the lower package substrate, a molding member positioned on the lower package substrate and covering at least a portion of the semiconductor chip, a conductive post positioned within the molding member and connected to the lower redistribution pattern, and an upper package substrate positioned on an upper surface of the molding member and including an upper redistribution insulation layer and an upper redistribution pattern positioned within the upper redistribution insulation layer. The molding member and the conductive post define a trench. The trench includes a first inner surface recessed toward a bottom surface of the molding member from the upper surface of the molding member and a second inner surface corresponding to a side surface of the conductive post. The first inner surface of the trench has one of a convex shape and a concave shape.

According to an aspect of the present disclosure, a semiconductor package includes a lower package substrate including a lower redistribution insulation layer and a lower redistribution pattern positioned within the lower redistribution insulation layer, a semiconductor chip mounted on the lower package substrate, a connection terminal positioned between the lower package substrate and the semiconductor chip, and connecting the semiconductor chip to the lower package substrate, a molding member positioned on the lower package substrate and covering at least a portion of the semiconductor chip, a conductive post positioned within the molding member and connected to the lower redistribution pattern, and an upper package substrate positioned on the molding member and including an upper redistribution insulation layer and an upper redistribution pattern positioned within the upper redistribution insulation layer. The conductive post includes a first part positioned on the lower redistribution pattern and a second part positioned on the first part and contacting the upper redistribution insulation layer of the upper package substrate. A width of the first part and a width of the second part are different from each other. An upper region of the second part includes a curved surface.

According to an aspect of the present disclosure, a trench including a curved surface is formed in a molding member positioned in a region where the molding member, a conductive post, and an upper redistribution insulation layer included in a upper redistribution substrate contact each other, and the upper redistribution insulation layer positioned in the region where the molding member, the conductive post, and the upper insulation layer which are different from each other material-wise and contact each other may include the curved surface to reduce a stress concentration.

Accordingly, cracks due to such a stress concentration in the region where the molding member, conductive post and the upper redistribution insulation layer are in contact with each other, may be prevented from occurring, thereby improving the reliability and productivity of the semiconductor package.

### BRIEF DESCRIPTION OF THE DRAWINGS

FIG. 1 is a cross-sectional view of a semiconductor package according to an embodiment.

FIG. 2 is a partial enlarged view of a region P1 of FIG. 1.

FIG. 3 to FIG. 11 are partial enlarged views showing each of a region P2 to a region P10 corresponding to a region P1 of FIG. 1 according to some embodiments.

FIG. 12 to FIG. 16 and FIG. 18 to FIG. 20 are cross-sectional views sequentially showing a manufacturing method of a semiconductor package according to an embodiment.

FIG. 17 is a cross-sectional view showing a manufacturing method of a semiconductor package according to some embodiments.

### DETAILED DESCRIPTION

The present invention will be described more fully hereinafter with reference to the accompanying drawings, in which embodiments of the invention are shown. As those skilled in the art would realize, the described embodiments may be modified in various different ways, all without departing from the spirit or scope of the present invention.

In order to clearly explain the present invention, portions that are not directly related to the present invention are omitted, and the same reference numerals are attached to the same or similar constituent elements through the entire specification.

Further, in the drawings, the sizes and thicknesses of the components are exemplarily provided for convenience of description, and the present invention is not limited to those shown in the drawings. In the drawings, the thickness of layers, films, panels, regions, etc., are exaggerated for clarity. In the drawings, the thickness of layers, films, panels, regions, etc., are exaggerated for convenience of description.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in this specification, the phrase “on a plane” means viewing a target portion from the top, and the phrase “on a cross-section” means viewing a cross-section formed by vertically cutting a target portion from the side.

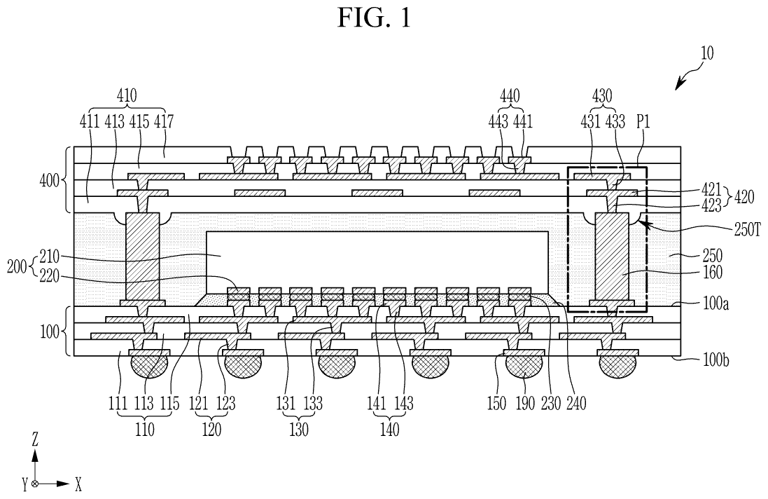

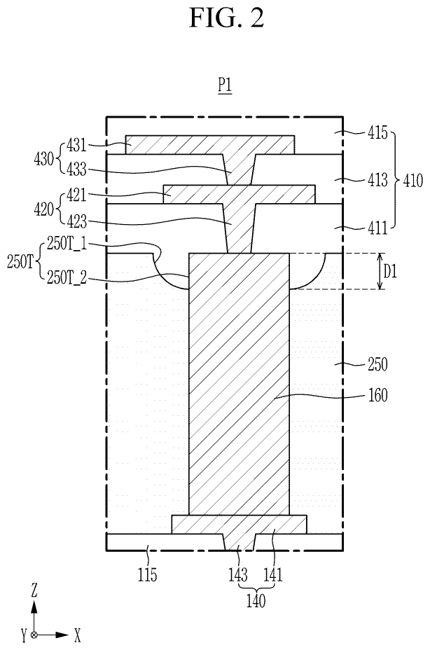

Hereinafter, a semiconductor package according to an embodiment is described with reference to FIG. 1 and FIG. 2.

FIG. 1 is a cross-sectional view of a semiconductor package according to an embodiment. FIG. 2 is a partial enlarged view of a region P1 of FIG. 1.

Referring to FIG. 1 and FIG. 2, a semiconductor package 10 according to an embodiment may include a lower redistribution substrate 100 (i.e., a lower package substrate), a conductive post 160, an external connection terminal 190, a lower semiconductor chip 200, a chip connection terminal 230, an underfill member 240, a molding member 250, and an upper redistribution substrate 400 (i.e., an upper package substrate).

The lower redistribution substrate 100 may include a lower redistribution insulation layer 110, a plurality of lower redistribution patterns 120, 130, and 140, and an external electrode pad 150.

The lower redistribution substrate 100 may include a first surface 100a and a second surface 100b. The direction parallel to the first surface 100a of the lower redistribution substrate 100 is defined as a first direction X, the direction parallel to the first surface 100a of the lower redistribution substrate 100 and vertical to the first direction X is defined as a second direction Y, and the direction vertical to the first surface 100a of the lower redistribution substrate 100 is defined as a third direction Z.

The lower redistribution insulation layer 110 may include a plurality of lower redistribution insulation layers 111, 113, and 115. The lower redistribution insulation layer 110 may include a first lower redistribution insulation layer 111, a second lower redistribution insulation layer 113, and a third lower redistribution insulation layer 115 stacked sequentially.

In FIG. 1, the lower redistribution insulation layer 110 is shown as including three insulating layers, but the number of the insulating layers included in the lower redistribution insulation layer 110 is not limited thereto and may be changed in various ways. For example, some of the first to third lower redistribution insulation layers 111, 113, and 115 may be omitted, or other insulating layers may be included in addition to the first to third lower redistribution insulation layers 111, 113, and 115.

In some embodiments, the insulating layer included in the lower redistribution substrate 100 may consist of one insulating layer.

Each of the first to third lower redistribution insulation layers 111, 113, and 115 may include or may be formed of, for example, an organic compound.

In some embodiments, each of the first to third lower redistribution insulation layers 111, 113, and 115 may include or may be formed of a photo imageable dielectric (PID) insulating material which may be processed using a photolithography process. For example, each of the first to third lower redistribution insulation layers 111, 113, and 115 may include or may be formed of a photosensitive polyimide (PSPI).

In some embodiments, each of the first to third lower redistribution insulation layers 111, 113, and 115 may include or may be formed of oxide or nitride. For example, each of the first to third lower redistribution insulation layers 111, 113, and 115 may include or may be formed of silicon oxide or silicon nitride.

The lower redistribution substrate 100 may include a first lower redistribution pattern 120, a second lower redistribution pattern 130, and a third lower redistribution pattern 140 sequentially positioned within the lower redistribution insulation layer 110.

In FIG. 1, the lower redistribution substrate 100 is shown as including three lower redistribution patterns 120, 130, and 140, but the number of the lower redistribution patterns included in the lower redistribution substrate 100 is not limited thereto and may be changed in various ways. For example, some of the first to third lower redistribution patterns 120, 130, and 140 may be omitted, or other conductive patterns may be included in addition to the first to third lower redistribution patterns 120, 130, and 140.

The first lower redistribution pattern 120 may include a first lower conductive line pattern 121 and a first lower conductive via pattern 123 connected thereto. The second lower redistribution pattern 130 may include a second lower conductive line pattern 131 and a second lower conductive via pattern 133 connected thereto. The third lower redistribution pattern 140 may include a third lower conductive line pattern 141 and a third lower conductive via pattern 143 connected thereto.

The first to third lower conductive line patterns 121, 131, and 141 may be positioned on the upper surfaces of the first to third lower redistribution insulation layers 111, 113, and 115, respectively.

The first to third conductive via patterns 123, 133, and 143 may penetrate the first to third lower redistribution insulation layers 111, 113, and 115, respectively. The first to third conductive via patterns 123, 133, and 143 may be connected to the first to third lower conductive line patterns 121, 131, and 141, respectively, or may be connected to the external electrode pad 150.

Widths of the first to third lower conductive line patterns 121, 131, and 141 along the first direction X may be larger than widths of the first to third lower conductive via patterns 123, 133, and 143 along the first direction X, respectively. Thicknesses of the first to third lower conductive line patterns 121, 131, and 141 along the third direction Z may be thinner than thicknesses of the first to third lower conductive via patterns 123, 133, and 143 along the third direction Z, respectively.

The first to third lower conductive via patterns 123, 133, and 143 may have a shape in which the width along the first direction gradually narrows in a direction from the first surface 100a toward the second surface 100b of the lower redistribution substrate 100.

Each of the first to third lower redistribution patterns 120, 130, and 140 consisting of the first to third lower conductive line patterns 121, 131, and 141 and the first to third lower conductive via patterns 123, 133, and 143 may have a ‘T’ shape on a cross-section.

There may be no boundary between the first to third lower conductive line patterns 121, 131, and 141 and the first to third conductive via patterns 123, 133, and 143. However, the relationship between the first to third lower conductive line patterns 121, 131, and 141 and the first to third lower conductive via patterns 123, 133, and 143, and the shape of the cross-section of the first to third lower redistribution patterns 120, 130, and 140. is not limited thereto and may be changed in various ways. For example, the first to third lower conductive line patterns 121, 131, and 141 and the first to third lower conductive via patterns 123, 133, and 143 may be composed of separate configurations, and there may be the boundary between the first to third lower conductive line patterns 121, 131, and 141 and the first to third lower conductive via patterns 123, 133, and 143.

Specifically, the first lower conductive line pattern 121 of the first lower redistribution pattern 120 may be positioned on a portion of the upper surface of the first lower redistribution insulation layer 111. The upper surface of the first lower conductive line pattern 121 may be covered by the second lower redistribution insulation layer 113.

The first lower conductive via pattern 123 of the first lower redistribution pattern 120 may extend in the vertical direction through the first lower redistribution insulation layer 111 and may be connected to each of the first lower conductive line pattern 121 and the external electrode pad 150. That is, the first lower conductive via pattern 123 may be positioned within the opening of the first lower redistribution insulation layer 111 that exposes a portion of the upper surface of the external electrode pad 150.

The second lower conductive line pattern 131 of the second lower redistribution pattern 130 may be positioned on a portion of the upper surface of the second lower redistribution insulation layer 113. The upper surface of the second lower conductive line pattern 131 may be covered by the third lower redistribution insulation layer 115.

The second lower conductive via pattern 133 of the second lower redistribution pattern 130 may extend in the vertical direction through the second lower redistribution insulation layer 113 and may be connected to each of the first lower conductive line pattern 121 and the second lower conductive line pattern 131. That is, the second lower conductive via pattern 133 may be positioned within the opening of the second lower redistribution insulation layer 113, which exposes a portion of the upper surface of the first lower conductive line pattern 121.

The third lower conductive line pattern 141 of the third lower redistribution pattern 140 may be positioned on a portion of the upper surface of the third lower redistribution insulation layer 115. The third lower conductive line pattern 141 may be positioned on the first surface 100a of the lower redistribution substrate 100.

The third lower conductive via pattern 143 of the third lower redistribution pattern 140 may extend in the vertical direction through the third lower redistribution insulation layer 115 and may be connected to each of the second lower conductive line pattern 131 and the third lower conductive line pattern 141. That is, the third lower conductive via pattern 143 may be positioned within the opening of the third lower redistribution insulation layer 115, which exposes a portion of the upper surface of the second lower conductive line pattern 131.

A portion of the third lower conductive line pattern 141 of the third lower redistribution pattern 140 may be positioned below the semiconductor chip 200 and may serve as a pad connected to the semiconductor chip 200. The remaining part of the third lower conductive line pattern 141 of the third lower redistribution pattern 140 may be positioned on the outside of one side and the other side of the semiconductor chip 200 and may serve as a pad connected to the conductive post 160.

Each of the first to third lower redistribution patterns 120, 130, and 140 may include or may be formed of a conductive material. For example, each of the first to third lower redistribution patterns 120, 130, and 140 may include or may be formed of metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof. However, the material included in the first to third lower redistribution patterns 120, 130, and 140 is not limited thereto and may be changed in various ways.

Although not shown in FIG. 1 and FIG. 2, in some embodiments, a seed layer (not shown) may be positioned between the first lower conductive line pattern 121 and each of the first lower redistribution insulation layer 111 and the lower conductive via pattern 123, between the second lower conductive line pattern 131 and each of the second lower redistribution insulation layer 113 and the second lower conductive via pattern 133, and between the third lower conductive line pattern 141 and each of the third lower redistribution insulation layer 115 and the third lower conductive via pattern 143.

In some embodiments, each of the first to third lower redistribution patterns 120, 130, and 140 may include or may be formed of copper (Cu), and at least a portion of the seed layer may serve as a diffusion barrier layer.

The seed layer may include or may be formed of a conductive material. For example, the seed layer may include at least one of copper (Cu), titanium (Ti), titanium tungsten (TiW), titanium nitride (TiN), tantalum (Ta), tantalum nitride (TaN), chromium (Cr), aluminum (Al), and a combination thereof. In some embodiments, the seed layer may be Cu/Ti, in which copper is stacked on titanium, or Cu/TiW, in which copper is stacked on titanium tungsten.

The external electrode pad 150 may have a uniform thickness, extend in the first direction X, may be disposed to be in contact with the second surface 100b of the lower redistribution substrate 100. That is, the external electrode pad 150 may be buried from the second surface 100b of the lower redistribution substrate 100 toward the first surface 100a. In some embodiments, the external electrode pad 150 may extend in the first direction X, and the entirety of the external electrode pad 150 may have a uniform thickness. The external electrode pad 150 may be buried in the lower redistribution substrate 100, and may be exposed at the second surface 100b of the lower redistribution substrate 100.

The external electrode pad 150 nay be embedded and positioned within the first lower redistribution insulation layer 111 of the lower redistribution substrate 100. The bottom surface of the external electrode pad 150 may be coplanar with the second surface 100b of the lower redistribution substrate 100, and the upper surface of the external electrode pad 150 may be covered by the first lower redistribution insulation layer 111. However, the position of the external electrode pad 150 is not limited thereto and may be changed in various ways. For example, the external electrode pad 150 may be positioned on the second surface 100b of the lower redistribution substrate 100, and the bottom surface of the external electrode pad 150 may be lower than the second surface 100b.

The external electrode pad 150 may include or may be formed of a conductive material. For example, the external electrode pad 150 may include or may be formed of copper (Cu), aluminum (Al), tungsten (W), titanium (Ti), tantalum (Ta), indium (In), molybdenum (Mo), manganese (Mn), and cobalt. Contains metals such as (Co), tin (Sn), nickel (Ni), magnesium (Mg), rhenium (Re), beryllium (Be), gallium (Ga), ruthenium (Ru), or an alloy thereof. However, the material included in the external electrode pad 150 is not limited thereto and may be changed in various ways.

The external connection terminal 190 may be positioned on the external electrode pad 150. The external connection terminal 190 may be positioned to be protruded above the second surface 100b of the lower redistribution substrate 100 and may be connected to the external electrode pad 150.

The external connection terminal 190 may be, for example, at least one of a solder ball, a pillar, and a bump. However, the type of the external connection terminal 190 is not limited thereto and may be changed in various ways.

The external connection terminal 190 may include or may be formed of a conductive material. For example, the external connection terminal 190 may include or may be formed of metal such as tin (Sn), silver (Ag), zinc (Zn), lead (Pb), and an alloy thereof. However, the conductive material included in the external connection terminal 190 is not limited thereto and may be changed in various ways.

The semiconductor package 10 according to an embodiment may be electrically connected to and mounted on a module substrate or a system board of an electronic product through an external connection terminal 190. The external electrode pad 150 may perform a role of an under bump metallurgy (UBM) where the external connection terminal 190 is positioned.

The semiconductor chip 200 may be mounted on the first surface 100a of the lower redistribution substrate 100. For example, the semiconductor chip 200 may be mounted on the lower redistribution substrate 100 by using a flip chip process.

The semiconductor chip 200 may be a memory chip or a logic chip. For example, the memory chip may be a volatile memory chip such as DRAM (Dynamic Random Access Memory) and SRAM (Static Random Access Memory), or a non-volatile memory chip such as PRAM (Phase-change Random Access Memory), MRAM (Magnetoresistive Random Access Memory), FeRAM (Ferroelectric Random Access Memory), and RRAM (Resistive Random Access Memory).

In some embodiments, the memory chip may be a high bandwidth memory (HBM) DRAM semiconductor chip. In some embodiments, the logic chip may be a microprocessor, an analog element, or a digital signal processor.

The semiconductor chip 200 may include a semiconductor substrate 210 and a plurality of chip pads 220 positioned on one surface of the semiconductor substrate 210. The plurality of chip pads 220 positioned on one surface of the semiconductor substrate 210 may face the first surface 100a of the lower redistribution substrate 100. In other words, the plurality of chip pads 220 may face a portion of the third lower conductive line pattern 131 of the third lower redistribution pattern 130 positioned on the first surface 100a of the lower redistribution substrate 100.

The semiconductor substrate 210 may include or may be formed of, for example, silicon (Si). In some embodiments, the semiconductor substrate 210 may include or may be formed of SiGe. In some embodiments, the semiconductor substrate may include or may be formed of a compound semiconductor such as silicon carbide (SiC), gallium arsenide (GaAs), indium arsenide (InAs), and indium phosphide (InP). However, the material included in the semiconductor substrate 210 is not limited thereto and may be changed in various ways.

The semiconductor substrate 210 may have an active surface and an inactive surface opposite to the active surface. For example, the semiconductor substrate 210 may be mounted so that the active surface faces the first surface 100a of the lower redistribution substrate 100.

In the semiconductor chip 200, a semiconductor device including a plurality of various types of individual devices may be positioned on the active surface of the semiconductor substrate 210.

The chip connection terminal 230 may be positioned between the chip pad 220 of the semiconductor chip 200 and the third lower conductive line pattern 141 of the third lower redistribution pattern 130. The chip connection terminal 230 may electrically connect the chip pad 220 of the semiconductor chip 200 to the third lower conductive line pattern 141.

The chip connection terminal 230 may be, for example, at least one of a solder ball, a pillar, and a bump. However, the type of the chip connection terminal 230 is not limited thereto and may be changed in various ways.

The chip connection terminal 230 may include or may be formed of a conductive material. For example, the chip connection terminal 230 may include or may be formed of metal such as tin (Sn), silver (Ag), zinc (Zn), lead (Pb), and an alloy thereof. However, the conductive material included in the chip connection terminal 230 is not limited thereto and may be changed in various ways.

The semiconductor chip 200 may receive at least one of a control signal, a power signal, and a ground signal for the operation of the semiconductor chip 200 from the outside, receive a data signal to be stored in the semiconductor chip 200 from the outside, or provide a data stored in the semiconductor chip 200 to the outside through the chip connection terminal 230, the first to third lower redistribution patterns 120, 130, and 140 of the lower redistribution substrate 100, the external electrode pad 150, and the external connection terminal 190.

The underfill member 240 may be positioned between the semiconductor chip 200 and the lower redistribution substrate 100. The underfill member 240 may fill a gap region remaining after the third lower conductive line pattern 141 of the third lower redistribution pattern 140 and the chip connection terminal 230 are formed between the first surface 100a of the lower redistribution substrate 100 and the semiconductor chip 200.

The underfill member 240 may cover the first surface 100a of the lower redistribution substrate 100, one surface of the semiconductor chip 200 facing the first surface 100a of the lower redistribution substrate 100, the side of the chip connection terminal 230, and the third lower conductive line pattern 141 of the third lower redistribution pattern 140.

In some embodiments, opposite ends of the underfill member 240 may extend in opposite directions of the first direction X beyond opposite sides of the semiconductor chip 200. The end of the underfill member 240 may be positioned more protruded than the opposite sides of the semiconductor chip 200. That is, part of the underfill member 240 may overlap the semiconductor chip 200 in the third direction Z of the vertical direction, and the remaining part may not overlap the semiconductor chip 200 in the third direction Z of the vertical direction.

In some embodiments, the underfill member 240 positioned between the lower redistribution substrate 100 and the semiconductor chip 200 may be omitted.

The underfill member 240 may include or may be formed of an insulating material. For example, the underfill member 240 may include or may be formed of an epoxy-based polymer. However, the material included in the underfill member 240 is not limited thereto and may be changed in various ways.

In some embodiments, the underfill member 240 may be a non-conductive film (NCF).

The molding member 250 may be positioned on the first surface 100a of the lower redistribution substrate 100. The molding member 250 may cover the first surface 100a of the lower redistribution substrate 100, the underfill member 240, and at least a portion of the semiconductor chip 200. For example, the molding member 250 may completely cover the semiconductor chip 200. That is, the molding member 250 may cover opposite sides and the upper surface of the semiconductor chip 200.

Accordingly, the upper surface of the molding member 250 may be positioned at a higher level than the upper surface of the semiconductor chip 200. However, the arrangement relationship between the molding member 250 and the semiconductor chip 200 is not limited to this and may be changed in various ways.

The molding member 250 may include or may be formed of an insulating material. For example, the molding member 250 may include or may be formed of a polymer such as an epoxy molding compound (EMC). In some embodiments, the molding member 250 may include or may be formed of an epoxy-based material, a thermosetting material, a thermoplastic material, or an UV-treated material. However, the material included in the molding member 250 is not limited to this and may be changed in various ways.

The conductive post 160 may be positioned on the first surface 100a of the lower redistribution substrate 100. The conductive post 160 may be positioned on opposite sides of the semiconductor chip 200 within the molding member 250. The conductive post 160 may be positioned to be spaced apart from one side and the other side of the semiconductor chip 200 in the first direction X, which is the horizontal direction and may have a post shape or a pillar shape extending through the molding member 250 in the third direction Z, which is the vertical direction.

The conductive post 160 may be positioned on the first surface 100a of the lower redistribution substrate 100 and be disposed on the third lower redistribution pattern 140, which functions as a pad. In other words, the conductive post 160 may be connected to the third lower conductive line pattern 141 of the third lower redistribution pattern 140.

The conductive post 160 may be electrically connected to the semiconductor chip 200 through at least a part among the first to third lower redistribution insulation layers 110, 120, and 130 and may be electrically connected to the external connection terminal 190 through at least a part among the first to third lower redistribution insulation layers 110, 120, and 130 and the external electrode pad 150.

The conductive post 160 may include or may be formed of a conductive material. For example, the conductive post 160 may include copper (Cu). However, the material included in the conductive post 160 is not limited to this and may be variously changed.

The upper surface of the conductive post 160 may be positioned at substantially the same level as the upper surface of the molding member 250. In some embodiments, the upper surface of the conductive post 160 may be positioned at a higher level than the upper surface of the semiconductor chip 200.

The molding member 250 may include a trench 250T positioned on opposite sides of the upper region of the conductive post 160 and recessed from the upper surface of the molding member 250 toward the bottom surface thereof.

The side positioned in the upper region of the conductive post 160 may be surrounded by the trench 250T of the molding member 250, and the side of the conductive post 160 positioned in the remaining region of the conductive post 160 may be surrounded by the molding member 250. For example, the conductive post 160 may extend beyond a recessed upper surface of the molding member 250 in a direction away from the lower redistribution substrate 100. The side surface of the conductive post 160 may be connected to the recessed upper surface of the molding member 250.

The trench 250T of the molding member 250 may have a concave shape from the upper surface of the molding member 250 toward the bottom surface, and the trench 250T of the molding member 250 may include a curved surface.

Specifically, as shown in FIG. 2, the trench 250T of the molding member 250 may include a first inner surface 250T_1 defined by the molding member 250 and a second inner surface 250T_2 defined by the side of the conductive post 160. For example, the first inner surface 250T_1 may correspond to a recessed upper surface of the molding member 250 toward the lower redistribution substrate 100, and the second inner surface 250T_2 may correspond to an exposed side surface of the conductive post 160. That is, the first inner surface 250T_1 of the trench 250T of the molding member 250 may be composed of the molding member 250, and the second inner surface 250T_2 may be composed of the side of the conductive post 160.

The first inner surface 250T_1 and the second inner surface 250T_2 of the trench 250T of the molding member 250 may face each other in the first direction X.

One end of the first inner surface 250T_1 (i.e., an upper end of the first inner surface 250T_1) of the trench 250T of the molding member 250 may be positioned at substantially the same level as the upper surface of the molding member 250, and the other end (i.e., a lower end) may be positioned on the side of the conductive post 160.

For example, the lower end of the first inner surface 250T_1 may be connected to the second inner surface 250T_2. Terms such as “same,” “equal,” “planar,” or “coplanar,” as used herein encompass near identicality including variations that may occur, for example, due to manufacturing processes. The term “substantially” may be used herein to emphasize this meaning, unless the context or other statements indicate otherwise.

One end of the second inner surface 250T_2 (i.e., an upper end of the second inner surface 250_T2) of the trench 250T of the molding member 250 may be positioned at substantially the same level as the upper surface of the conductive post 160, and the other end (i.e., a lower end) may be positioned on the side surface of the conductive post 160. That is, the other end of the first inner surface 250T_1 of the trench 250T of the molding member 250 may be connected to the other end of the second inner surface 250T_2. The other end of the first inner surface 250T_1 may be in contact with the side surface of the conductive post 160. The term “contact,” or “in contact with,” as used herein, refers to a direct connection (i.e., physical touching) unless the context indicates otherwise.

The trench 250T of the molding member 250 may be positioned at a level between the upper surface of the semiconductor chip 200 and the upper surface of the molding member 250. The trench 250T of the molding member 250 may be positioned at a level between the upper surface of the semiconductor chip 200 and the upper surface of the conductive post 160. That is, the other end of the first inner surface 250T_1 of the trench 250T of the molding member 250 and the other end of the second inner surface 250T_2 may be positioned at a level higher than the upper surface of the semiconductor chip 200. However, the arrangement relationship between the trench 250T of the molding member 250 and the upper surface of the semiconductor chip 200 is not limited thereto and may be changed in various ways. For example, the other end of the first inner surface 250T_1 of the trench 250T of the molding member 250 and the other end of the second inner surface 250T_2 may be positioned at a level lower than the upper surface of the semiconductor chip 200.

In some embodiments, the first inner surface 250T_1 of the trench 250T of the molding member 250 may include a curved shape, and the second inner surface 250T_2 may include a straight line shape.

The first inner surface 250T_1 of the trench 250T of the molding member 250 may have a rounded shape so that it approaches the side of the conductive post 160 from the upper surface of the molding member 250. That is, the first inner surface 250T 1 of the trench 250T of the molding member 250 may have a curved shape that is concave in a direction away from the second inner surface 250T_2. In other words, the molding member 250 in contact with the upper region of the conductive post 160 may have a concave recessed shape by the trench 250T of the molding member 250.

The second inner surface 250T_2 of the trench 250T of the molding member 250 may have a straight line shape extending in the third direction Z along the side of the conductive post 160. However, the shapes of the first inner surface 250T_1 and second inner surface 250T_2 of the trench 250T of the molding member 250 are not limited to this and may be changed in various ways.

A width of the trench 250T of the molding member 250 along the first direction X may decrease as it approaches the lower redistribution substrate 100 (i.e., in a direction toward the lower redistribution substrate 100). That is, a distance, in the first direction X, between the first inner surface 250T_1 and the second inner surface 250T_2 of the trench 250T of the molding member 250 may decrease as it approaches the lower redistribution substrate 100.

The upper redistribution substrate 400 may be positioned on the molding member 250 and the conductive post 160. That is, the upper redistribution substrate 400 may cover the upper surface of the molding member 250 and the upper surface of the conductive post 160.

The upper redistribution substrate 400 may include an upper redistribution insulation layer 410 and a plurality of upper redistribution patterns 420, 430, and 440. The upper redistribution insulation layer 410 may include a plurality of upper

redistribution insulation layers 411, 413, 415, and 417. The upper redistribution insulation layer 410 may include a first upper redistribution insulation layer 411, a second upper redistribution insulation layer 413, a third upper redistribution insulation layer 415, and a fourth upper redistribution insulation layer 417 stacked sequentially on the molding member 250 and the conductive post 160.

In FIG. 1, the upper redistribution insulation layer 410 is shown as including four insulating layers, but the number of the insulating layers included in the upper redistribution insulation layer 410 is not limited to this and may be changed in various ways. For example, some of the first to fourth upper redistribution insulation layers 411, 413, 415, and 417 may be omitted, or other insulating layers may be included in addition to the first to fourth upper redistribution insulation layers 411, 413, 415, and 417.

In some embodiments, the insulating layer included in the upper redistribution substrate 400 may consist of one insulating layer.

Each of the first to fourth upper redistribution insulation layers 411, 413, 415, and 417 may include the same material as the first to third lower redistribution insulation layers 111, 113, and 115 described above. For example, each of the first to fourth upper redistribution insulation layers 411, 413, 415, and 417 may include or may be formed of a photo imageable dielectric (PID) insulating material which may be processed using a photolithography process.

In some embodiments, each of the first to fourth upper redistribution insulation layers 411, 413, 415, and 417 may include or may be formed of silicon oxide or silicon nitride.

The upper redistribution substrate 400 may include a first upper redistribution pattern 420, a second upper redistribution pattern 430, and a third upper redistribution pattern 440 sequentially positioned within the upper redistribution insulation layer 410.

In FIG. 1, the upper redistribution substrate 400 is shown as including three upper redistribution patterns 420, 430, and 440, but the number of the upper redistribution patterns included in the upper redistribution substrate 400 is not limited to this and may be changed in various ways. For example, some of the first to third upper redistribution patterns 420, 430, and 440 may be omitted, or other conductive patterns may be included in addition to the first to third upper redistribution patterns 420, 430, and 440.

The first to third upper redistribution patterns 420, 430, and 440 may each include first to third upper conductive line patterns 421, 431, and 441 and first to third upper conductive via patterns 423, 433, and 443 integral with each other. In some embodiments, the first to third upper redistribution patterns 420, 430, and 440 may include first to third upper conductive line patterns 421, 431, and 441, respectively. The first to third upper redistribution patterns 420, 430, and 440 may further include first to third upper conductive via patterns 423, 433, and 443, respectively. The first to third upper conductive line patterns 421, 431, and 441 may be integrated with (i.e., may be connected to) the first to third upper via patterns 423, 433, and 443, respectively.

The first to third upper conductive line patterns 421, 431, and 441 may be positioned on upper surfaces of the first to third upper redistribution insulation layers 411, 413, and 415, respectively.

The first to third plurality of upper conductive via patterns 423, 433, and 443 may penetrate the first to third upper redistribution insulation layers 411, 413, and 415, respectively. The first to third upper conductive via patterns 423, 433, and 443 may be connected to the first to third upper conductive line patterns 421, 431, and 441, respectively, or may be connected to the upper surface of the conductive post 160.

Widths of the first to third upper conductive line patterns 421, 431, and 441 along the first direction may be larger than widths the first to third upper conductive via patterns 423, 433, and 443 along the first direction X, respectively. Thicknesses of the first to third upper conductive line patterns 421, 431, and 441 along the third direction Z may be thinner than thicknesses of the first to third upper conductive via patterns 423, 433, and 443 along the third direction Z, respectively.

The first to third upper conductive via patterns 423, 433, and 443 may have a shape of which a width along the first direction gradually widens in a direction away from the upper surface of conductive post 160.

Each of the first to third upper redistribution patterns 420, 430, and 440, which consist of the first to third upper conductive line patterns 421, 431, and 441 and the first to third upper conductive via patterns 423, 433, and 443, may have a ‘T’ shape on a cross-section.

There may be no boundary between the first to third upper conductive line patterns 421, 431, and 441 and the first to third upper conductive via patterns 423, 433, and 443. However, the relationship of the first to third upper conductive line patterns 421, 431, and 441 and the first to third upper conductive via patterns 423, 433, and 443, and the shape of the cross-section of the first to third upper redistribution patterns 420, 430, and 440 are not limited thereto, and may be variously changed. For example, the first to third upper conductive line patterns 421, 431, and 441 and the first to third upper conductive via patterns 423, 433, and 443 may be configured as separate configurations, and there may be an interface between the first to third upper conductive line patterns 421, 431, and 441 and the first to third upper conductive via patterns 423, 433, and 443.

Specifically, the first upper redistribution insulation layer 411 may cover the upper surface of the molding member 250 and the upper surface of the conductive post 160. The first upper redistribution insulation layer 411 may be positioned within the trench 250T of the molding member 250 and may be positioned on the side of the upper region of the conductive post 160. For example, a first portion of the first upper redistribution insulation layer 411 may fill the trench 250T.

The first upper redistribution insulation layer 411 may include the first portion that is positioned within the trench 250T of the molding member 250. The first portion of the first upper redistribution insulation layer 411 may cover the first inner surface 250T_1 and the second inner surface 250T_2 of the trench 250T of the molding member 250.

The first portion of the first upper redistribution insulation layer 411 may be positioned within the trench 250T of the molding member 250, and may contact the molding member 250 and the conductive post 160.

As the first portion of the first upper redistribution insulation layer 411 is positioned within the trench 250T of the molding member 250, opposite sides positioned in the upper region of the conductive post 160 may be surrounded by the first upper redistribution insulation layer 411. However, the arrangement relationship between the first upper redistribution insulation layer 411 positioned within the trench 250T of the molding member 250 and the molding member 250 and the arrangement relationship between the first upper redistribution insulation layer 411 and the conductive post 160 are not limited thereto, and a separate layer may be further positioned between the first upper redistribution insulation layer 411 positioned in the trench 250T of the molding member 250 and the molding member 250 and between the first upper redistribution insulation layer 411 positioned in the trench 250T of the molding member 250 and the conductive post 160.

Opposite sides of the first portion of the first upper redistribution insulation layer 411 positioned within the trench 250T of the molding member 250 may have the substantially same shape as the first inner surface 250T_1 and the second inner surface 250T_2 of the trench 250T of the molding member 250, respectively.

One side of the first portion of the first upper redistribution insulation layer 411 positioned within the trench 250T of the molding member 250 and in contact with the molding member 250 has a convex shape toward the molding member 250, and the other side of the first portion of the first upper redistribution insulation layer 411 in contact with the side of the conductive post 160 may have a straight line shape extending in the third direction Z, which is the vertical direction.

One side of the first portion of the first upper redistribution insulation layer 411 positioned within the trench 250T of the molding member 250 may have a curved shape that is convex in a direction away from the other side of the first portion of the first upper redistribution insulation layer 411 positioned within the trench 250T of the molding member 250. In other words, the molding member 250 positioned on the side of the upper region of the conductive post 160 may have a concave shape recessed by the first portion of the first upper redistribution insulation layer 411 within the trench 250T.

A width of the first portion of the first upper redistribution insulation layer 411 positioned within the trench 250T of the molding member 250 along the first direction may be smaller as it approaches the lower redistribution substrate 100 (i.e., in a direction toward the lower redistribution substrate 100).

The first portion of the first upper redistribution insulation layer 411 positioned within the trench 250T of the molding member 250 may have a first thickness D1, which corresponds to a maximum thickness of the first portion of the first upper redistribution insulation layer 411. Here, the first thickness D1 of the first upper redistribution insulation layer 411 refers to a thickness along the third direction Z, which is the vertical direction. In some embodiments, the first thickness D1 may correspond to a length of an exposed portion of the conductive post 160 which extends above the recessed upper surface of the molding member 250. The length of the exposed portion may be measured in the third direction Z. In some embodiments, an upper surface of the first portion of the first upper redistribution insulation layer 411 may be coplanar with the upper surface of the conductive post 160.

In some embodiments, a curvature radius (i.e., a radius of a curvature) of one side of the first portion of the first upper redistribution insulation layer 411 that is in contact with the first inner surface 250T_1 of the trench 250T of the molding member 250 and that has the curved shape may be 0.5 times to 1.5 times of the first thickness D1 of the first portion of the first upper redistribution insulation layer 411. However, the curvature radius of one side of the first upper redistribution insulation layer 411 positioned within the trench 250T of the molding member 250 is not limited to the above-mentioned numerical range and may be changed in various ways. In some embodiments, the curvature radius may correspond to a radius of a circle that best fits the first inner surface 250T_1.

As the first portion of the first upper redistribution insulation layer 411 that is positioned in the region and that is in contact with the molding member 250 and the conductive post 160 includes the curved surface, it is possible to prevent a stress from being concentrated at the corner where the molding member 250, the conductive post 160, and the first upper redistribution insulation layer 411 contact each other, thereby preventing cracks from occurring due to this stress concentration.

In addition, as the first portion of the first upper redistribution insulation layer 411 is positioned within the trench 250T of the molding member 250, the contact area between the first upper redistribution insulation layer 411 and the molding member 250 increases, thereby increasing the adherence of the first upper redistribution insulation layer 411 to the molding member 250 and preventing the first upper redistribution insulation layer 411 from delaminating from the molding member 250.

The first upper conductive line pattern 421 of the first upper redistribution pattern 420 may be positioned on a portion of the upper surface of the first upper redistribution insulation layer 411. The upper surface of the first upper conductive line pattern 421 may be covered by the second upper redistribution insulation layer 413.

The first upper conductive via pattern 423 of the first upper redistribution pattern 420 may extend in the vertical direction through the first upper redistribution insulation layer 411 and may be connected to at least a portion of the first upper conductive line pattern 421 and the conductive post 160. That is, the first upper conductive via pattern 423 may be positioned within the opening of the first upper redistribution insulation layer 411, which exposes a portion of the upper surface of the conductive post 160.

The second upper conductive line pattern 431 of the second upper redistribution pattern 430 may be positioned on a portion of the upper surface of the second upper redistribution insulation layer 413. The upper surface of the second upper conductive line pattern 431 may be covered by the third upper redistribution insulation layer 415.

The second upper conductive via pattern 433 of the second upper redistribution pattern 430 may extend in the vertical direction through the second upper redistribution insulation layer 413, and may be connected to at least part of the first upper conductive line pattern 421 and at least part of the second upper conductive line pattern 431. That is, the second upper conductive via pattern 433 may be positioned within the opening of the second upper redistribution insulation layer 413, which exposes a portion of the upper surface of the first upper conductive line pattern 421.

The third upper conductive line pattern 441 of the third upper redistribution pattern 440 may be positioned on a portion of the upper surface of the third upper redistribution insulation layer 415. A portion of the upper surface of the third upper conductive line pattern 441 may be exposed by an opening included in the fourth upper redistribution insulation layer 417.

The third upper conductive via pattern 443 of the third upper redistribution pattern 440 may extend in the vertical direction through the third upper redistribution insulation layer 415 and may be connected to at least a portion of the second upper conductive line pattern 431 and the third upper conductive line pattern 441. That is, the third upper conductive via pattern 443 may be positioned within the opening of the third upper redistribution insulation layer 415, which exposes a portion of the upper surface of the second upper conductive line pattern 431.

Each of the first to third upper redistribution patterns 420, 430, and 440 may include or may be formed of a conductive material. For example, each of the first to third upper redistribution patterns 420, 430, and 440 may include or may be formed of metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof. However, the materials included in the first to third upper redistribution patterns 420, 430, and 440 are not limited thereto and may be changed in various ways.

Although not shown in FIG. 1 and FIG. 2, in some embodiments, a seed layer (not shown) may be positioned between the first upper conductive line pattern 421 and each of the first upper redistribution insulation layer 411 and the first upper conductive via pattern 423, between the second upper conductive line pattern 431 and each of the second upper redistribution insulation layer 413 and the second upper conductive via pattern 433, and between the third upper conductive line pattern 441 and each of the third upper redistribution insulation layer 415 and the third upper conductive via pattern 443.

The seed layer may include or may be formed of a conductive material. For example, the seed layer may include or may be formed of one of copper (Cu), titanium (Ti), titanium tungsten (TiW), titanium nitride (TiN), tantalum (Ta), tantalum nitride (TaN), chromium (Cr), aluminum (Al) and a combination thereof. In some embodiments, the seed layer may be Cu/Ti, in which copper is laminated on titanium, or Cu/TiW, in which copper is laminated on titanium tungsten.

Although not shown in FIG. 1, in some embodiments, an upper semiconductor chip (not shown) may be mounted on the upper redistribution substrate 400. The upper semiconductor chip mounted on the upper redistribution substrate 400 may be a different type of a semiconductor chip from the semiconductor chip 200 mounted on the lower redistribution substrate 100. For example, the semiconductor chip 200 mounted on the lower redistribution substrate 100 may be a logic chip, and the upper semiconductor chip mounted on the upper redistribution substrate 400 may be a memory chip.

In some embodiments, the upper semiconductor chip mounted on the upper redistribution substrate 400 may be the same semiconductor chip as the semiconductor chip 200 mounted on the lower redistribution substrate 100.

In some embodiments, the upper semiconductor chip mounted on the upper redistribution substrate 400 may be mounted on the upper redistribution substrate 400 in a flip chip process. The upper semiconductor chip on the upper redistribution substrate 400 may be connected to at least a portion of the upper redistribution patterns 420, 430, and 440. For example, the upper semiconductor chip mounted on the upper redistribution substrate 400 may be electrically connected to the third upper redistribution pattern 440 through a connection terminal such as a solder ball, a pillar, and a bump.

In some embodiments, the upper semiconductor chip mounted on the upper redistribution substrate 400 may be directly connected to the third upper redistribution pattern 440. In some embodiments, the upper semiconductor chip mounted on the upper redistribution substrate 400 may be electrically connected to the third upper redistribution pattern 440 by using a wire bonding method.

Although not shown, in some embodiments, an upper molding member (not shown) may be positioned on the upper redistribution substrate 400. When the upper semiconductor chip is mounted on the upper redistribution substrate 400, the upper molding member positioned on the upper redistribution substrate 400 may cover at least a portion of the upper semiconductor chip.

For a comparison of the semiconductor package 10 according to an embodiment, the semiconductor package according to a reference example may be considered. In the semiconductor package according to the reference example, the first upper redistribution insulation layer may be in vertical contact with the molding member and the conductive post.

In the semiconductor package according to the reference example, the first upper redistribution insulation layer may be in vertically contact with the corner of the molding member and the corner of the conductive post. In other words, the corner of the upper region of the conductive post in contact with the molding member may be in contact the bottom surface of the first upper redistribution insulation layer in a vertical direction.

As above-described, when the first upper redistribution insulation layer is in vertical contact with the boundary surface of the molding member and the conductive post, a stress may be concentrated in a region where the molding member, the conductive post, and the first upper redistribution insulation layer with different coefficients of thermal expansion (CTE) are in contact with each other.

In the semiconductor package 10 according to an embodiment, as the trench 250T formed on the molding member 250 in contact with the side of the upper region of the conductive post 160 has the curved shape, the first upper redistribution insulation layer 411, which is positioned within the trench 250T of the molding member 250 and is disposed in the region in contact with the molding member 250 and the conductive post 160, may include the curved surface.

When the first portion of the first upper redistribution insulation layer 411 which is in contact with the molding member 250 and the conductive post 160 includes the curved surface, it is possible to minimize the stress concentration at the corners where the molding member 250, the conductive post 160, and the first upper redistribution insulation layer 411 contact with each other.

Accordingly, cracks due to the stress concentration at the corners where the molding member 250, the conductive post 160, and the first upper redistribution insulation layer 411 contact with each other may be prevented from occurring, thereby improving the reliability and the productivity of the semiconductor package.

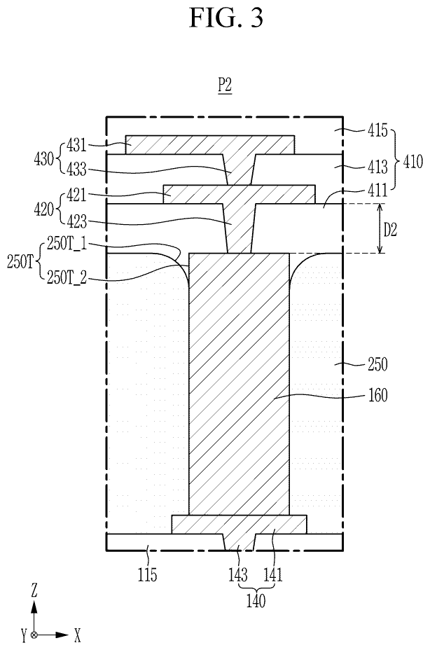

Hereinafter, the semiconductor packages according to various embodiments are described with reference to FIG. 3 to FIG. 11. In the following embodiments, the same components as the previously described embodiments will be referred to by the same reference numerals, redundant descriptions will be omitted or simplified, and differences will be mainly explained.

FIG. 3 to FIG. 11 are cross-sectional views showing semiconductor packages according to some embodiments. Specifically, FIG. 3 to FIG. 11 are partial enlarged views showing each of the region P2 to the region P10 region corresponding to the region P1 in FIG. 1.

According to the embodiments shown in FIG. 3 to FIG. 5, unlike the embodiment shown in FIG. 2, there are differences in the shape of the trench 250T of the molding member 250, and the shape of the first upper redistribution insulation layer 410 positioned within the trench 250T of the molding member 250 is changed.

Specifically, referring to FIG. 3, the trench 250T of the molding member 250 may include a first inner surface 250T_1 defined by the molding member 250 and a second inner surface 250T_2 defined by the side of the conductive post 160.

In the present embodiment, the first inner surface 250T_1 of the trench 250T of the molding member 250 may include a curved shape, and the second inner surface 250T_2 may include a straight line shape.

The first inner surface 250T_1 of the trench 250T of the molding member 250 may have a concave shape in a direction approaching the second inner surface 250T_2. That is, the edge portion of the molding member 250 that is in contact with the side of the upper region of the conductive post 160 may have a rounded curved shape.

The second inner surface 250T_2 of the trench 250T of the molding member 250 may have a straight line shape extending in the third direction Z along the side of the conductive post 160.

The width of the trench 250T of the molding member 250 along the first direction X may decrease as it approaches the lower redistribution substrate 100. That is, the distance, in the first direction X, between the first inner surface 250T_1 and the second inner surface 250T_2 of the trench 250T of the molding member 250 may decrease as it approaches the lower redistribution substrate 100.

The first upper redistribution insulation layer 411 may cover the upper surface of the molding member 250 and the upper surface of the conductive post 160. The first upper redistribution insulation layer 411 may be positioned within the trench 250T of the molding member 250 and may be positioned on the side of the upper region of the conductive post 160.

Opposite sides of a first portion of the first upper redistribution insulation layer 411 positioned within the trench 250T of the molding member 250 may have substantially the same shape as the first inner surface 250T_1 and the second inner surface 250T_2 of the trench 250T of the molding member 250.

One side of the first portion of the first upper redistribution insulation layer 411 that is positioned within the trench 250T of the molding member 250 and that is in contact with the molding member 250 may have a concave shape in a direction approaching the other side of the first upper redistribution insulation layer 411, which is in contact with the side of the conductive post 160. The other side of the first portion of the first upper redistribution insulation layer 411 that is in contact with the side of the conductive post 160 may have a straight line shape extending in the third direction Z, which is the vertical direction. In other words, the first portion of the first upper redistribution insulation layer 411 positioned on the side of the upper region of the conductive post 160 may have a recessed and concave shape. The first portion of the first upper redistribution insulation layer 411 may contact the molding member 250 and the conductive post 160.

The first upper redistribution insulation layer 411 may include a second portion that covers the upper surface of the molding member 250, the upper surface of the conductive post 160, and the first portion of the first upper redistribution insulation layer 411 positioned within the trench 250T of the molding member 250 and that extends in the first direction X may have a second thickness D2. Here, the second thickness D2 of the first upper redistribution insulation layer 411 may refer to a thickness along the third direction Z, which is the vertical direction.

In some embodiments, the curvature radius of one side of the first upper redistribution insulation layer 411 that is in contact with the first inner surface 250T_1 of the trench 250T of the molding member 250 and that has the curved shape may be about 0.5 to 1.5 times of the second thickness D2 of the first upper redistribution insulation layer 411. However, the curvature radius of one side of the first portion of the first upper redistribution insulation layer 411 positioned within the trench 250T of the molding member 250 is not limited to the above-mentioned numerical range and may be changed in various ways.

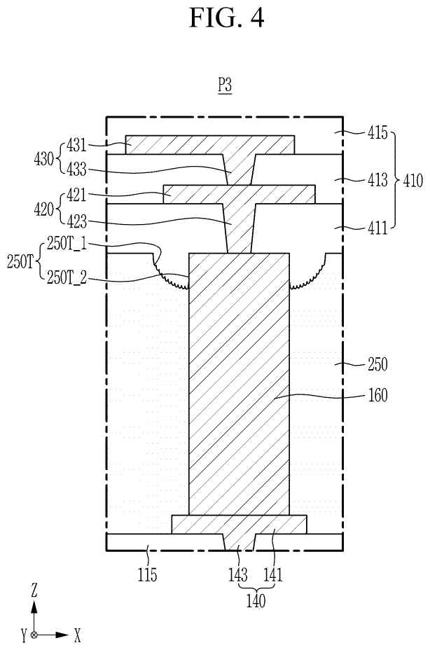

Referring to FIG. 4, the first inner surface 250T_1 of the trench 250T of the molding member 250, unlike the first inner surface 250T_1 of the trench 250T of the molding member 250 according to the embodiment shown in FIG. 2, may include a plurality of protruding portions along the first inner surface 250T_1.

In some embodiments, the first inner surface 250T_1 of the trench 250T of the molding member 250 may include a plurality of protruding portions protruded toward the molding member 250.

The ends of the protruding portions of the first inner surface 250T_1 of the trench 250T of the molding member 250 may have a curved shape convex toward the molding member 250. However, the shape of the ends of the protruding portions of the first inner surface 250T_1 of the trench 250T of the molding member 250 is not limited to this and may be changed in various ways.

The surface of the first inner surface 250T_1 of the trench 250T of the molding member 250 may have a curve due to the plurality of protruding portions. That is, the surface of the first inner surface 250T_1 of the trench 250T of the molding member 250 may have a structure of protrusions and retrusions due to a plurality of protruding portions protruded toward the molding member 250.

Accordingly, the first inner surface 250T_1 and the second inner surface 250T_2 of the trench 250T of the molding member 250 may have different surface roughness. That is, the surface of the first inner surface 250T_1 of the trench 250T of the molding member 250 may be rougher than the surface of the second inner surface 250T_2. In other words, the second inner surface 250T_2 of the trench 250T of the molding member 250 may have a relatively smooth surface compared to the first inner surface 250T_1.

In some embodiments, opposite sides of a first portion of the first upper redistribution insulation layer 411 positioned within the trench 250T of molding member 250 may have substantially the same shape as the first inner surface 250T_1 and the second inner surface 250T_2 of the trench 250T of the molding member 250, respectively.

One side of the first portion of the first upper redistribution insulation layer 411 that is positioned within the trench 250T of the molding member 250 and that is in contact with the molding member 250 may include a plurality of protruding portions each of which has a convex shape toward the molding member 250, and the other side of the first portion of the first upper redistribution insulation layer 411 that is in contact with the side of the conductive post 160 may have a straight line shape extending in the third direction Z, which is the vertical direction. That is, the surface of one side of the first portion of the first upper redistribution insulation layer 411 positioned within the trench 250T of the molding member 250 may have a convex shape with a plurality of protruding portions.

In addition, the one side of the first portion of the first upper redistribution insulation layer 411 that is positioned within the trench 250T of the molding member 250 and that is in contact with the molding member 250 may have a surface rougher than the surface of the other side of the first portion of the first upper redistribution insulation layer 411 in contact with the conductive post 160. In other words, the other side of the first portion of the first upper redistribution insulation layer 411 positioned within the trench 250T of the molding member 250 may have a relatively smooth surface compared to the one side of the first portion of the first upper redistribution insulation layer 411 positioned within the trench 250T of the molding member 250.

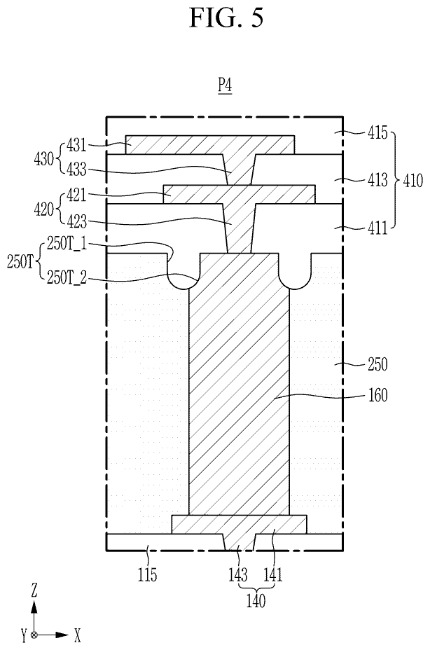

Referring to FIG. 5, the second inner surface 250T_2 of the trench 250T of the molding member 250, unlike the second inner surface 250T_2 of the trench 250T of the molding member 250 according to the embodiment shown in FIG. 2, may include a curved surface.

In some embodiments, a part of the trench 250T of the molding member 250 may be a part recessed toward the bottom surface from the upper surface of the molding member 250, and the remaining part may be a portion recessed from the upper surface of conductive post 160 toward the bottom surface.

In the present embodiment, each of the first inner surface 250T_1 and the second inner surface 250T_2 of the trench 250T of the molding member 250 may have a curved shape. The first inner surface 250T_1 of the trench 250T of the molding member 250 may have a concave shape toward the molding member 250, and the second inner surface 250T_2 of the conductive post 160 may have a concave shape toward the conductive post 160. However, the curved shape of each of the first inner surface 250T_1 and the second inner surface 250T_2 of the trench 250T of the molding member 250 are not limited thereto and may be changed in various ways. For example, the first inner surface 250T_1 of the trench 250T of the molding member 250 may have substantially the same shape as the first inner surface 250T_1 of the trench 250T of the molding member 250 according to the embodiment shown in FIG. 3.

The trench 250T of the molding member 250 may have a concave shape recessed from each of the upper surface of the molding member 250 and the upper surface of the conductive post 160 toward the bottom surface of the molding member 250 and the bottom surface of the conductive post 160. In other words, the trench 250T of the molding member 250 may have a ‘U’ shape in the cross-section. That is, the trench 250T of the molding member 250 may have a semicircular shape in the cross-section.

In some embodiments, opposite sides of the first portion of the first upper redistribution insulation layer 411 positioned within the trench 250T of the molding member 250 may have substantially the same shape as the first inner surface 250T_1 and the second inner surface 250T_2 of the trench 250T of the molding member 250.

The first portion of the first upper redistribution insulation layer 411 positioned within the trench 250T of the molding member 250 may have a convex shape which corresponds to a concavely recessed upper surface of the molding member 250, and a concavely recessed upper surface of the conductive post 160.

In some embodiments, the first portion of the first upper redistribution insulation layer 411 positioned within the trench 250T of the molding member 250 may overlap the side of the conductive post 160 in the third direction Z, which is the vertical direction.

According to the semiconductor package according to the embodiments shown in FIG. 3 to FIG. 5, like the semiconductor package 10 of FIG. 1 according to an embodiment, as the trench 250T included in the molding member 250, which is in contact with the side surface positioned in the upper region of the conductive post 160, has the curved shape, the first portion of the first upper redistribution insulation layer 411, which is positioned within the trench 250T of the molding member 250 and is in contact with the molding member 250 and the conductive post 160, may include the curved surface.

Accordingly, it may have substantially the same effects as the semiconductor package 10 of FIG. 1 according to the embodiment described above.

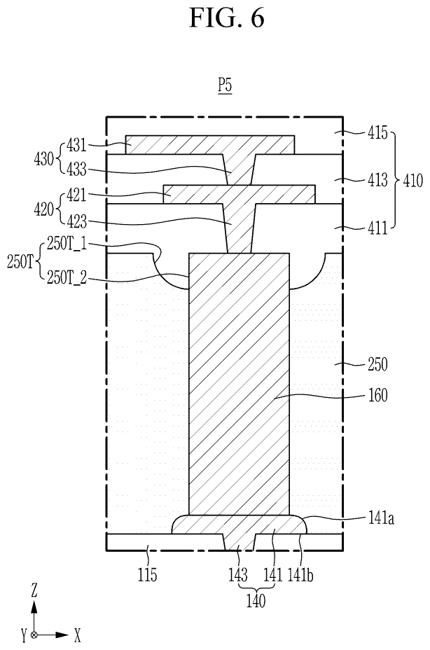

According to the embodiment shown in FIG. 6, unlike the embodiment shown in FIG. 2, there is a difference in the shape of the third conductive line pattern 141 of the third lower redistribution pattern 140, which is connected to conductive post 160.

Referring to FIG. 6, the upper surface of the third conductive line pattern 141 of the third lower redistribution pattern 140 connected to the conductive post 160 may include a curved shape.

Specifically, the edge of the upper surface 141a of the third conductive line pattern 141 connected to the conductive post 160 may have a rounded shape which is curved from the upper surface 141a of the third conductive line pattern 141 toward the bottom surface 141b thereof. The upper surface 141a and the bottom surface 141b of the third conductive line pattern 141 connected to the conductive post 160 may be connected with a curved line.

The edge of the upper surface 141a of the third conductive line pattern 141 connected to the conductive post 160 may include a convex shape toward the molding member 250. However, the shape of the edge of the upper surface 141a of the third conductive line pattern 141 connected to the conductive post 160 is not limited thereto and may be changed in various ways. For example, the edge of the upper surface 141a of the third conductive line pattern 141 connected to the conductive post 160 may include a concave shape. In other words, the upper surface 141a of the third conductive line pattern 141 connected to the conductive post 160 may have a concave shape recessed by the molding member 250.

In FIG. 6, the trench 250T of the molding member 250 is shown as having substantially the same shape as the trench 250T of the molding member 250 according to the embodiment shown in FIG. 2, but in the present embodiment, the shape of the trench 250T of the molding member 250 is not limited thereto and may be variously changed. For example, in the present embodiment, the shape of the trench 250T of the molding member 250 may have substantially the same shape as the trench 250T of the molding member 250 according to the embodiments shown in FIG. 3 to FIG. 5.

According to the semiconductor package according to the embodiments shown in FIG. 6, it may have substantially the same effects as the semiconductor package 10 of FIG. 1 according to an embodiment.

In addition, as the upper surface 141a of the third conductive line pattern 141, which is connected to the conductive post 160 and is in contact with the molding member 250 and the third lower redistribution insulation layer 115, includes the curved shape, it is possible to prevent cracks from occurring due to the stress concentration at the corner in which the molding member 250, the third conductive line pattern 141 of the third lower redistribution pattern 140, and the third lower redistribution insulation layer 115 are in contact with each other.

Accordingly, the cracks are prevented from occurring in the first upper redistribution insulation layer 411 in contact with the conductive post 160 and simultaneously the cracks are prevented from occurring in the third lower redistribution insulation layer 115 in contact with third lower redistribution pattern 140, thereby improving the reliability and the productivity of the semiconductor package.

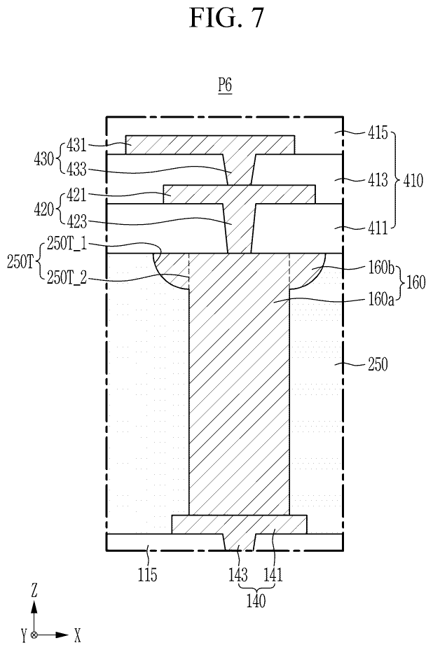

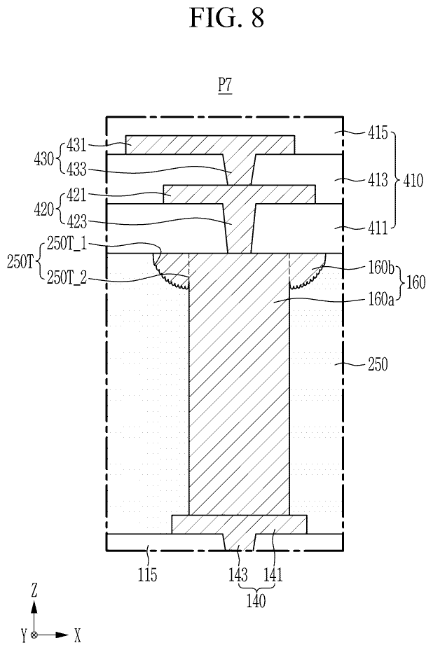

According to the embodiments shown in FIG. 7 and FIG. 8, unlike the embodiment shown in FIG. 2 and FIG. 4, there is a difference in that the shape of the conductive post 160 changes as the conductive post 160 is positioned within the trench 250T of the molding member 250.

Referring to FIG. 7, unlike the embodiment shown in FIG. 2, the conductive post 160 may be positioned within the trench 250T of the molding member 250.

In some embodiments, the conductive post 160 may include a first portion 160a connected to the third lower redistribution pattern 140 and extending in the third direction Z, which is the vertical direction, and a second portion 160b positioned within the trench 250T of the molding member 250.

The first portion 160a and the second portion 160b of the conductive post 160 may be formed by separate processes. For example, after forming the first portion 160a of the conductive post 160, the second portion 160b of the conductive post 160 may be formed within the trench 250T of the molding member 250.

There may be an interface between the first portion 160a and the second portion 160b of the conductive post 160. However, the method of forming the first portion 160a and the second portion 160b of the conductive post 160 is not limited to this and may be changed in various ways. For example, the first portion 160a and the second portion 160b of conductive post 160 may be formed simultaneously by the same process.

Additionally, since the first portion 160a and the second portion 160b of the conductive post 160 include the same material, there may be no boundary between the first portion 160a and the second portion 160b of the conductive post 160.

The first portion 160a of the conductive post 160 may have a post or pillar shape extending in the third direction Z. The first portion 160a of the conductive post 160 may have a short axis in the first direction X and a long axis in the third direction Z, and may have a rectangle shape in the cross-section. However, the shape of the cross-section of the first portion 160a of the conductive post 160 is not limited to this and can be changed in various ways.

The second portion 160b of the conductive post 160, referring to FIG. 2, may have the substantially same shape as the first portion of the first upper redistribution insulation layer 411 positioned within the trench 250T of the molding member 250.

In addition, opposite sides of the second portion 160b of the conductive post 160 positioned within the trench 250T of the molding member 250 may have the substantially same shape as the first inner surface 250T_1 and the second inner surface 250T_2 of the trench 250T of the molding member 250.

One side of the second portion 160b of the conductive post 160 that is positioned within the trench 250T of the molding member 250, and that is in contact with the molding member 250 may have a convex shape toward the molding member 250. The second portion 160b of the conductive post 160 may have a convex

shape in a direction away from the side of the first portion 160a, and the molding member 250 in contact with the second portion 160b of the conductive post 160 may have a concave shape recessed by the second portion 160b of the conductive post 160.

The other side of the first upper redistribution insulation layer 411, which is in contact with the side of the first portion 160a of the conductive post 160, may have a straight line shape extending in the third direction Z, which is the vertical direction.

In some embodiments, the curvature radius of one side of the second portion 160b of the conductive post 160 in contact with the molding member 250 may be about 0.5 to 1.5 times the maximum thickness of the second portion 160b in the third direction Z or the vertical direction. An upper surface of the second portion 160b may be coplanar with the first portion 160a or may be coplanar with an upper surface of the molding member 250. However, the curvature radius of one side of the second portion 160b of the conductive post 160 is not limited to the above-mentioned numerical range and may be variously changed.

Referring to FIG. 8, unlike the embodiment shown in FIG. 7, there is a difference in the shape of the second portion 160b of the conductive post 160 positioned within the trench 250T of the molding member 250.

In some embodiments, the first inner surface 250T_1 of the trench 250T of the molding member 250 may include a plurality of protruding portions protruded toward the second portion 160b of the conductive post 160.

Opposite sides of the second portion 160b of the conductive post 160 positioned within the trench 250T of the molding member 250 may have substantially the same shape as the first inner surface 250T_1 and the second inner surface 250T_2 of the trench 250T of the molding member 250, respectively.

One side of the second portion 160b of the conductive post 160 in contact with the molding member 250 includes a plurality of protruding portions each of which has a convex shape toward the molding member 250, and the other side of the second portion 160b of the conductive post 160 in contact with the side of the first portion 160a of the conductive post 160 may have a straight line shape extending in the third direction Z, which is the vertical direction.

The one side of the second portion 160b of the conductive post 160 positioned within the trench 250T of the molding member 250 may have a curved surface with protrusions and retrusions due to the plurality of protruding portions.

Additionally, the surface of the second portion 160b of the conductive post 160 in contact with the molding member 250 may be rougher than the surface of the first portion 160a of the conductive post 160. That is, the side of the first portion 160a of the conductive post 160 may have a relatively smooth surface compared to one side of the second portion 160b of the conductive post 160.

According to the semiconductor package according to the embodiment shown in FIG. 7 and FIG. 8, as the conductive post 160 positioned in the region in contact with the molding member 250 and the first upper redistribution insulation layer 411 includes the curved surface, it is possible to prevent cracks from occurring due to the stress concentration at the corner where the molding member 250, the conductive post 160, and the first upper redistribution insulation layer 411 are in contact with each other.

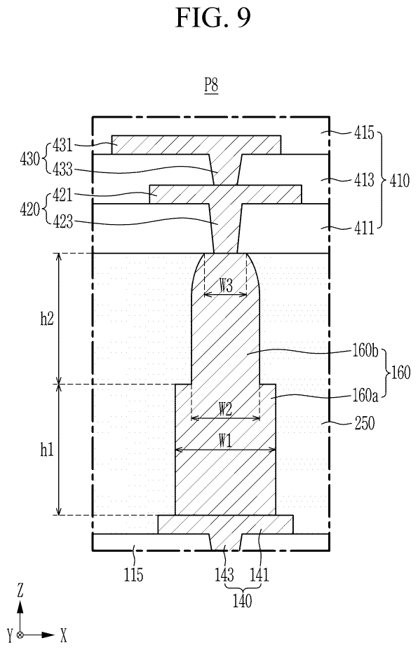

According to the embodiments shown in FIG. 9 to FIG. 11, unlike the embodiment shown in FIG. 2, there are differences in the shape of the conductive post 160 and the arrangement of the first upper redistribution insulation layer 411.

According to the embodiment shown in FIG. 9, unlike the embodiment shown in FIG. 2, the conductive post 160 has a multi-stage structure, and the side of the upper region of the conductive post 160 may include a curved surface.

The molding member 250 in contact with the side of the upper region of conductive post 160 does not include a trench (referring to 250T in FIG. 2), and the bottom surface of the first upper redistribution insulation layer 411 may be positioned at the substantially same level as the upper surface of the conductive post 160.

The conductive post 160 may have a multi-stage structure. The conductive post 160 may include a first portion 160a and a second portion 160b sequentially stacked on the third lower redistribution pattern 140.

In some embodiments, there is no boundary between the first portion 160a and the second portion 160b of the conductive post 160, but the first portion 160a and the second portion 160b of the conductive post 160 may be formed by separate processes, and there may be an interface between the first portion 160a and the second portion 160b of the conductive post 160.

In some embodiments, the first portion 160a and the second portion 160b of the conductive post 160 may be formed simultaneously by the same process, and there may be no interface between the first portion 160a and the second portion 160b of the conductive post 160.

The first portion 160a of the conductive post 160 may extend on the third lower redistribution pattern 140 in the third direction Z, which is the vertical direction, and may have a post or pillar shape. For example, the first portion 160a of the conductive post 160 may have a short axis in the first direction X and a long axis in the third direction Z, and may have a rectangle shape on the cross-section.

The second portion 160b of the conductive post 160 may be positioned on the first portion 160a. The second portion 160b of the conductive post 160 may extend from the first portion 160a in the third direction Z, which is the vertical direction, and may be in contact with the first upper redistribution insulation layer 411.

The upper surface of the second portion 160b of the conductive post 160 may have a flat surface. The side of the upper region of the second portion 160b of the conductive post 160 may include a curved surface. That is, the upper surface and the side surface of the second portion 160b of the conductive post 160 may be connected by a curved line. In other words, the edge of the upper region of the second portion 160b of the conductive post 160 may have a rounded shape.

The first upper redistribution insulation layer 411 may cover the upper surface of the molding member 250 and the upper surface of the second portion 160b of the conductive post 160 and may be positioned at the higher level than the molding member 250 and the second portion 160b of the conductive post 160. The bottom surface of the first upper redistribution insulation layer 411 may be coplanar with the upper surface of the second portion 160b of the conductive post 160.

The first portion 160a of the conductive post 160 may have a first width W1 in the first direction X, the bottom surface of the second portion 160b of the conductive post 160 may have a second width W2 in the first direction, and the upper surface of the second portion 160b of the conductive post 160 may have a third width W3 in the first direction X. For example, the entirety of the first portion 160a may have the first width W1 in the first direction X, and the second portion 160b may have a decreasing width from the second width W2 to the third width W3 in the third direction Z away from the third lower redistribution pattern 140.

The first width W1 may be larger than the second width W2 and the third width W3, and the second width W2 may be larger than the third width W3. That is, as the width W1 of the first portion 160a of the conductive post 160 in the first direction X may be larger than the width W2 of the bottom surface of the second portion 160b and the width W3 of the upper surface in the first direction X, and the side of the uppermost region of the second portion 160b of the conductive post 160 may include the curved surface, the width W2 of the bottom surface of the second portion 160b of the conductive post 160 may be larger than the width W3 of the upper surface. However, the relationship between the first width W1, the second width W2, and the third width W3 is not limited thereto and may be changed in various ways.

The first portion 160a of the conductive post 160 may have a first height h1 in the third direction Z, which is the vertical direction, and the second portion 160b may have a second height h2 in the third direction Z, which is the vertical direction.

The first height h1 and the second height h2 may be different from each other. For example, the first height h1 may be larger than the second height h2. However, the relationship between the first height h1 and the second height h2 is not limited thereto and may be changed in various ways. For example, the first height h1 may be smaller than the second height h2.

As the conductive post 160 positioned at the corner where the molding member 250, the conductive post 160, and the first upper redistribution insulation layer 411 are in contact with each other includes the curved surface, it is possible to prevent stress concentration at the corner where the molding member 250, the conductive post 160, and the first upper redistribution insulation layer 411 contact with each other, thereby preventing cracks from occurring at the corner.

Accordingly, it may have substantially the same effects as the semiconductor package 10 according to the embodiment described above.

In addition, as the conductive post 160 has the multi-stage structure with the different widths and/or heights, the durability of the conductive post 160 may be improved and then it may be prevented from bending or being damaged by the stress occurring in the adjacent regions of the conductive post 160.

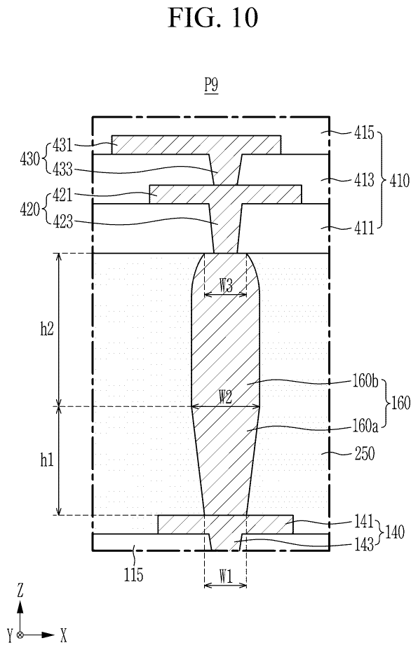

According to the embodiment shown in FIG. 10, unlike the embodiment shown in FIG. 9, there is a difference in the shape of the first portion 160a of the conductive post 160.

Referring to FIG. 10, the first portion 160a of the conductive post 160, unlike the first portion 160a of the conductive post 160 according to the embodiment shown in FIG. 9, may have a decreasing width in the first direction X in a direction toward the third lower redistribution pattern 140.

In some embodiments, there is no boundary between the first portion 160a and the second portion 160b of the conductive post 160, but the first portion 160a and the second portion 160b of the conductive post 160 may be formed by separate processes, and there may be an interface between the first portion 160a and the second portion 160b of the conductive post 160.

In some embodiments, the first portion 160a and the second portion 160b of the conductive post 160 may be formed simultaneously by the same process, and there may be no interface between the first portion 160a and the second portion 160b of the conductive post 160.

Specifically, the side of the first portion 160a of the conductive post 160 may include an inclined side with respect to the third lower redistribution pattern 140. The side of the first portion 160a of the conductive post 160 may have a tapered shape toward the third lower redistribution pattern 140. In other words, the first portion 160a of the conductive post 160 may have an inverse trapezoid shape on the cross-section.

The second portion 160b of the conductive post 160 has the substantially same shape as the second portion 160b of the conductive post 160 according to the embodiment shown in FIG. 9 so that the description thereof is omitted.

The bottom surface of the first portion 160a of the conductive post 160 may have a first width W1 in the first direction X, the bottom surface of the second portion 160b of the conductive post 160 may have a second width W2 in the first direction X, and the upper surface of the second portion 160b of the conductive post 160 may have a third width W3 in the first direction X.

The second width W2 may be larger than the first width W1 and the third width W3. The first width W1 and the third width W3 may be substantially the same as each other or different from each other. In other words, as the width of the first portion 160a of the conductive post 160 in the first direction decreases as it moves to the third lower redistribution pattern 140, the width W1 of the bottom surface of the first portion 160a of the conductive post 160 may be smaller than the width W2 of the upper surface of the first portion 160a of the conductive post 160.

The width of the bottom surface of the first portion 160a of the conductive post 160 may be substantially the same as or different from the width of the upper surface of the second portion 160b. For example, the first width W1 may be larger than the third width W3. However, the relationship between the first width W1, the second width W2, and the third width W3 is not limited thereto and may be changed in various ways.

The first portion 160a of the conductive post 160 may have a first height h1 in the third direction Z, which is the vertical direction, and the second portion 160b may have a second height h2 in the third direction Z, which is the vertical direction.

The first height h1 and the second height h2 may be different from each other. For example, the first height h1 may be smaller than the second height h2. However, the relationship between the first height h1 and the second height h2 is not limited thereto and may be changed in various ways. For example, the first height h1 may be larger than the second height h2.

The semiconductor package according to the present embodiment may have substantially the same effect as the semiconductor package according to the embodiment shown in FIG. 9.

The conductive post 160 having a multi-stage structure in which the first portion 160a of the conductive post 160 positioned at the bottom includes an inclined side, may have an increased contact area between the conductive post 160 and the molding member 250.

Accordingly, the adherence of the molding member 250 to the conductive post 160 is improved and the molding member 250 may be prevented from being delaminated from the conductive post 160.

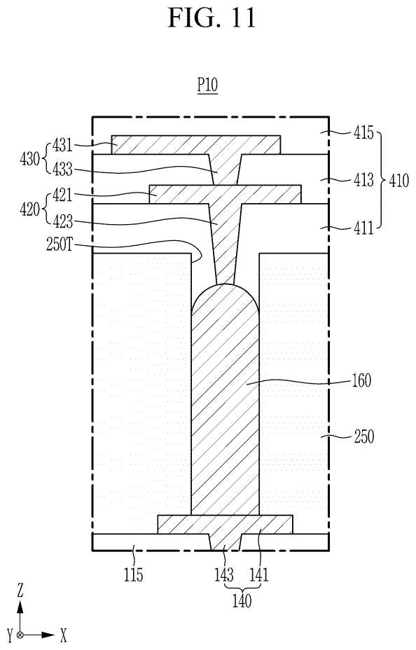

According to the embodiment shown in FIG. 11, unlike the embodiment shown in FIG. 2, there are differences in the upper surface of the conductive post 160 having a curved surface, and the arrangement relationship of the trench 250T of the molding member 250 and the conductive post 160.

Referring to FIG. 11, the upper surface of the conductive post 160 may include a curved surface. The upper surface of the conductive post 160 may have a convex shape toward the first upper redistribution insulation layer 411. However, the shape of the upper surface of the conductive post 160 is not limited thereto and may be changed in various ways. For example, the upper surface of the conductive post 160 may have a concave shape toward the bottom surface.

The molding member 250 may include a trench 250T recessed from the upper surface of the molding member 250 toward the upper surface of the conductive post 160. The trench 250T of the molding member 250 may be positioned on the conductive post 160. The trench 250T of the molding member 250 may overlap with the conductive post 160 in the third direction Z, which is the vertical direction. The upper surface of the conductive post 160 may be positioned at a lower level than the upper surface of the molding member 250.

The trench 250T of the molding member 250 may be defined by the molding member 250 and the conductive post 160. For example, the inner surfaces of opposite sides of the trench 250T of the molding member 250 may be composed of the molding member 250, and the bottom surface of the trench 250T may be composed of the upper surface of the conductive post 160.

The first upper redistribution insulation layer 411 may cover the upper surface of the molding member 250. A first portion of the first upper redistribution insulation layer 411 may be positioned within the trench 250T of the molding member 250. The first portion of the first upper redistribution insulation layer 411 positioned within the trench 250T of the molding member 250 may cover the upper surface of the conductive post 160. In some embodiments, the first portion of the first upper redistribution insulation layer 411 may contact the upper surface of the conductive post 160.

The first upper conductive via pattern 423 of the first upper redistribution pattern 420 may be positioned within the trench 250T of the molding member 250. The first upper conductive via pattern 423 may penetrate the first upper redistribution insulation layer 411 covering the upper surface of the molding member 250 and the first upper redistribution insulation layer 411 positioned within the trench 250T of the molding member 250 to be connected to the first upper conductive line pattern 421 and the conductive post 160.

As the upper surface of the conductive post 160 has the curved shape, it is possible to prevent cracks from occurring due to the stress concentration at the corner where the molding member 250, the conductive post 160, and the first upper redistribution insulation layer 411 contact with each other.

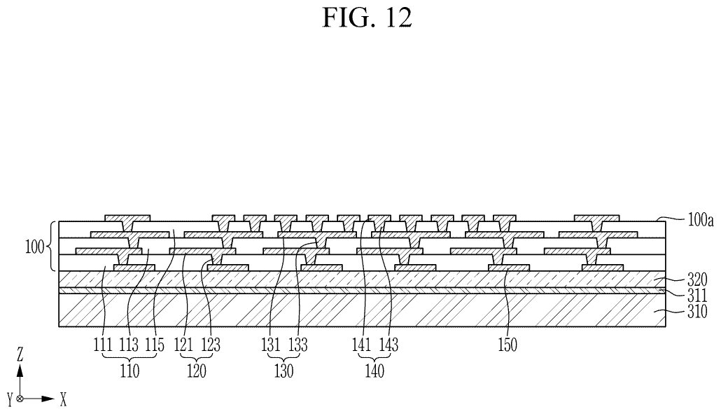

Hereinafter, the manufacturing method of the semiconductor package is described with reference to FIG. 12 to FIG. 20. Hereinafter, the same configuration described previously will be referred to by the same reference number, redundant explanations will be omitted or simplified, and the differences will be mainly explained.

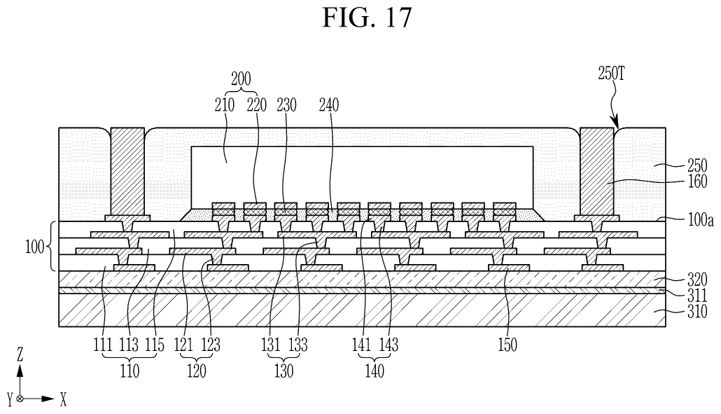

FIG. 12 to FIG. 16 and FIG. 18 to FIG. 20 are cross-sectional views sequentially showing a manufacturing method of a semiconductor package according to an embodiment. FIG. 17 is a cross-sectional view showing a manufacturing method of a semiconductor package according to some embodiments.

First, referring to FIG. 12, a cover layer 320 may be formed on a carrier substrate 310 to which a release film 311 is attached.

The cover layer 320 may include the same insulating material as the lower redistribution insulation layer (referring to 110 in FIG. 4). However, it is not limited to this, and the cover layer 320 may include an insulating material different from the lower redistribution insulation layer 110. For example, the cover layer 320 may include or may be formed of an organic compound.

In some embodiments, the cover layer 320 may include or may be formed of a photosensitive polyimide. In some embodiments, the cover layer 320 may include or may be formed of oxide or nitride.

The carrier substrate 310 may include a material that is stable against a baking processes, an etching processes, etc. The carrier substrate 310 may be a light-transmitting substrate, and may be separated and removed later by a laser ablation process.

In some embodiments, the carrier substrate 310 may be a heat resistance substrate such as a glass substrate, and may be separated and removed later by heating.

In some embodiments, the carrier substrate 310 may include or may be formed of a heat resistance organic polymer material such as polyimide, (poly (etheretherketone), PEEK), (poly (ethersulfone), PES), and (poly(phenylene sulfide) PPS). However, the material included in the carrier substrate 310 is not limited to this and may be changed in various ways.

For example, the release film 311 may allow the carrier substrate 310 to be separated later by laser. The release film 311 may be gasified by laser irradiation.

The release film 311 may include or may be formed of a carbon-based material layer. For example, the release film 311 may include or may be formed of an amorphous carbon layer (ACL), a hydrocarbon compound with a relatively high carbon content of about 85 wt % to about 99 wt % based on a total weight, or a spin-on hard mask (SOH), which is a membrane made of derivatives thereof.

Subsequently, an external electrode pad 150 may be formed on the cover layer 320. Forming the external electrode pad 150 may include forming and patterning a conductive material layer on the cover layer 320.

The external electrode pad 150 may be formed to have an overall uniform thickness on the upper surface of the cover layer 320, and the bottom surface of the external electrode pad 150 in contact with the upper surface of the cover layer 320 may have a flat shape.

The external electrode pad 150 may include or may be formed of a single metal material. However, it is not limited to this, and the external electrode pad 150 may have a multi-layer structure in which each layer is made of a different metal material.

Next, the first lower redistribution insulation layer 111 including an opening that exposes a portion of the external electrode pad 150 may be formed.

Forming the first lower redistribution insulation layer 111 may include forming an insulating material layer covering the external electrode pad 150 and the cover layer 320, and forming an opening by removing a portion of the insulating material layer through an exposing and developing in a photolithography process. For example, to form the opening in the first lower redistribution insulation layer 111, a reactive ion etching (RIE) process using plasma, a laser drilling, etc. may be performed.

The opening of the first lower redistribution insulation layer 111, which exposes the external electrode pad 150, may have a shape in which the width in the horizontal direction gradually narrows as it approaches the external electrode pad 150.

Subsequently, a first lower conductive line pattern 121 and a first lower conductive via pattern 123 may be formed on the first lower redistribution insulation layer 111.

The first lower conductive via pattern 123 is formed within the opening of the first lower redistribution insulation layer 111, and the first lower conductive line pattern 121 may be connected to the first lower conductive via pattern 123 and may be formed on a portion of the upper surface of the first lower redistribution insulation layer 111. The first lower conductive line pattern 121 and the first lower conductive via pattern 123 may constitute the first lower redistribution pattern 120.

In some embodiments, after forming a seed layer (not shown) on the first lower redistribution insulation layer 111, the first lower conductive line pattern 121 and the first lower conductive via pattern 123 may be formed on the seed layer.

For example, a seed metal layer may be formed on the upper surface of the first lower redistribution insulation layer 111, the inner surface of the opening formed in the first lower redistribution insulation layer 111, and the external electrode pad 150 exposed by the opening of the first lower redistribution insulation layer 111. For example, the seed metal layer may be formed through a physical vapor deposition.

Next, a photoresist pattern including an opening may be formed, and a plating process using a seed metal layer as a seed may be performed to form the first conductive line pattern 121 and the first conductive via pattern 123.

Next, the photoresist pattern may be removed, and a part of the seed metal layer exposed by removing the photoresist pattern may be removed. After the seed metal layer is removed, a seed layer positioned between the upper surface of the first lower redistribution insulation layer 111 and the first lower conductive line pattern 121, and between the first lower conductive via pattern 123 and the inner surface of the opening of the first lower redistribution insulation layer 111, and between the first lower conductive via pattern 123 and the external electrode pad 150 may be formed.

Next, on the first lower redistribution insulation layer 111 and the first lower redistribution pattern 120, a second lower redistribution insulation layer 113, a second lower redistribution pattern 130, a third lower redistribution insulation layer 115, and a third lower redistribution pattern 140 may be sequentially formed.

The second lower conductive via pattern 133 may be formed within the opening of the second lower redistribution insulation layer 113. The second lower conductive line pattern 131 may be connected to the second lower conductive via pattern 133 and may be formed on a portion of the upper surface of the second lower redistribution insulation layer 113. The second lower conductive line pattern 131 and the second lower conductive via pattern 133 may constitute a second lower redistribution pattern 130.

The third lower conductive via pattern 143 may be formed within the opening of the third lower redistribution insulation layer 115. The third lower conductive line pattern 141 may be connected to the third lower conductive via pattern 143 and may be formed on a portion of the upper surface of the third lower redistribution insulation layer 115. The third lower conductive line pattern 141 and the third lower conductive via pattern 143 may constitute a third lower redistribution pattern 140.

The method of forming the second lower redistribution insulation layer 113, the second lower redistribution pattern 130, the third lower redistribution insulation layer 115, and the third lower redistribution pattern 140 is substantially the same as the method of forming the first lower redistribution insulation layer 111 and the first lower redistribution pattern 120 described above so that the description thereof is omitted.

Additionally, in some embodiments, after forming a seed layer (not shown) on the second lower redistribution insulation layer 113, a second lower conductive line pattern 131 and a second lower conductive via pattern 133 may be formed on the seed layer.

Subsequently, after forming a seed layer (not shown) on the third lower redistribution insulation layer 115, a third lower conductive line pattern 141 and a third lower conductive via pattern 143 may be formed on the seed layer.

The first to third lower redistribution insulation layers 111, 113, and 115 may constitute a lower redistribution insulation layer 110, and the lower redistribution insulation layer 110, the first to third lower redistribution patterns 120, 130, and 140, and the external electrode pad 150 may constitute a lower redistribution substrate 100.

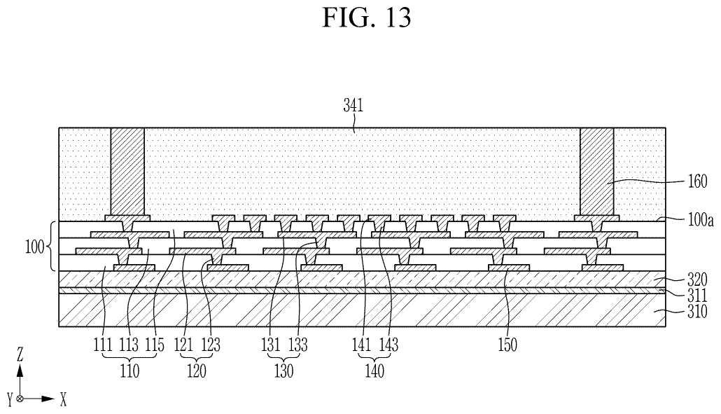

Next, referring to FIG. 13, a photoresist pattern 341 may be formed on the first surface 100a of the lower redistribution substrate 100.

Forming the photoresist pattern 341 may include forming an opening to expose a portion of the third conductive line pattern 141 of the third lower redistribution pattern 140. The opening of photoresist pattern 341 may define a region where a conductive post 160 will be formed through a subsequent process.

Subsequently, a conductive post 160 may be formed within the opening of photoresist pattern 341. The conductive post 160 may be formed on the third conductive line pattern 141 exposed through the opening of the photoresist pattern 341, and may be formed to fill at least part of the opening of the photoresist pattern 341.

The conductive post 160 may be formed of copper (Cu), but is not limited to this and may be changed in various ways.

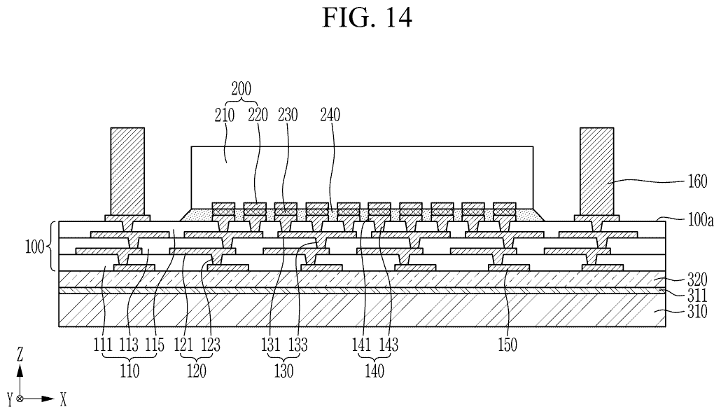

Next, referring to FIG. 14, a photoresist pattern 341 may be removed. For example, the photoresist pattern 341 may be removed by a strip process.

Next, a semiconductor chip 200 including a semiconductor substrate 210 and a plurality of chip pads 220 positioned at one surface of the semiconductor substrate 210 may be attached on the lower redistribution substrate 100. The semiconductor chip 200 may be attached on the first surface 100a of the lower redistribution substrate 100 so that the chip pad 220 faces the lower redistribution substrate 100. The semiconductor chip 200 may be positioned between the conductive posts 160.

Attaching the semiconductor chip 200 onto the lower redistribution substrate 100 may include forming a chip connection terminal 230 between the chip pad 220 of the semiconductor chip 200 and the third conductive line pattern 141 of the third lower redistribution pattern 140.

The chip connection terminal 230 may be, for example, at least one of a solder ball, a pillar, and a bump. However, the type of the chip connection terminal 230 is not limited to this and may be changed in various ways.

The chip pad 220 of the semiconductor chip 200 may be connected to the third conductive line pattern 141 of the third lower redistribution pattern 140 through the chip connection terminal 230.

Subsequently, an underfill member 240 that fills a gap between the semiconductor chip 200 and the lower redistribution substrate 100 may be formed. The underfill member 240 may surround the chip connection terminal 230. For example, the underfill member 240 may be formed by attaching the semiconductor chip 200 on the lower redistribution substrate 100 and then using a capillary underfill method.

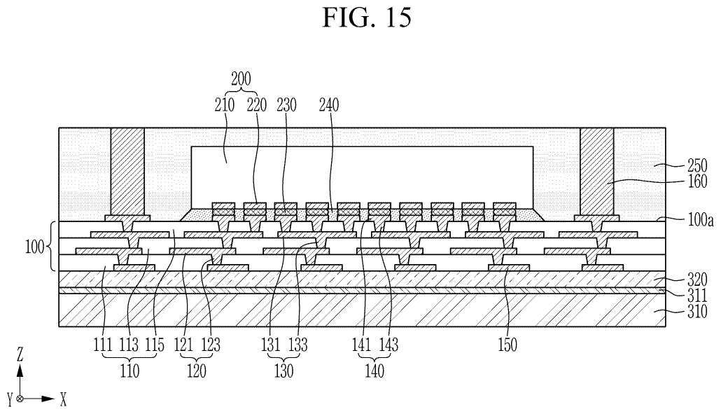

In some embodiments, the underfill member 240 may be formed by attaching a non-conductive film on the chip pad 220 of the semiconductor chip 200 and then attaching the semiconductor chip 200 on the lower redistribution substrate 100. Next, referring to FIG. 15, after forming the underfill member 240, a molding

member 250 for molding the semiconductor chip 200 may be formed. The molding member 250 may be formed to entirely cover the semiconductor chip 200 and the conductive post 160. The molding member 250 may be formed to cover the side and upper surfaces of the semiconductor chip 200 and the side and upper surfaces of the conductive post 160.

The molding member 250 may include or may be formed of an insulating material. For example, the molding member 250 may include or may be formed of a polymer such as an epoxy molding compound (EMC).

Forming the molding member 250 may include forming the molding member 250 and then performing a planarization process on the molding member 250 so that the upper surface of the conductive post 160 and the upper surface of the molding member 250 are substantially flat or coplanar. For example, the planarization process may be performed through a chemical mechanical polishing (CMP).

Accordingly, the upper surface of the conductive post 160 and the upper surface of the molding member 250 are positioned at substantially the same level, and the upper surface of the conductive post 160 and the upper surface of the molding member 250 may be positioned at a higher level than the upper surface of the semiconductor chip 200.

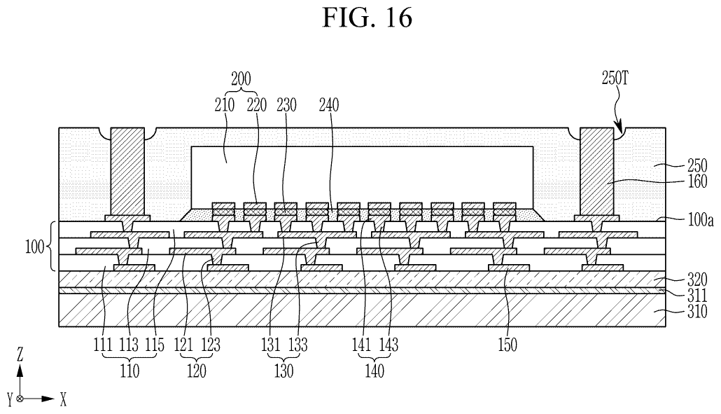

Next, referring to FIG. 16, a portion of the molding member 250 in contact with the side of the upper region of the conductive post 160 may be removed to form a trench 250T. For example, the upper surface of the molding member 250 may be recessed toward the bottom surface to form the trench 250T.

Specifically, the trench 250T of the molding member 250 may include a curved surface. The inner surface of the trench 250T of the molding member 250 may be defined by the sides of the molding member 250 and the conductive post 160.

The inner surface of the trench 250T of the molding member 250 defined by the molding member 250 includes a curved surface, and the inner surface of the trench 250T of the molding member 250 defined by the side of the conductive post 160 may have a straight line shape.

The inner surface of the trench 250T of the molding member 250 defined by the molding member 250 may have a concave shape in a direction away from the inner surface of the trench 250T of the molding member 250 defined by the side of the conductive post 160.

The trench 250T of the molding member 250 may have a concave shape which is formed by recessing the upper surface of the molding member 250 in contact with the side of the upper region of the conductive post 160 toward the lower redistribution substrate 100. However, the shape of the trench 250T of the molding member 250 is not limited to this and may be changed in various ways. For example, as shown in FIG. 17, the inner surface of the trench 250T of molding member 250 defined by molding member 250 may have a convex shape in a direction approaching the inner side of the trench 250T of the molding member 250 defined by the side of the conductive post 160. That is, the edge portion of the molding member 250 in contact with the side of the upper region of the conductive post 160 may have a rounded curved shape.

To form the trench 250T of the molding member 250, a laser drilling using plasma, a RIE process, and an etch back may be performed. However, the method for forming the trench 250T of the molding member 250 is not limited thereto and may be changed in various ways.

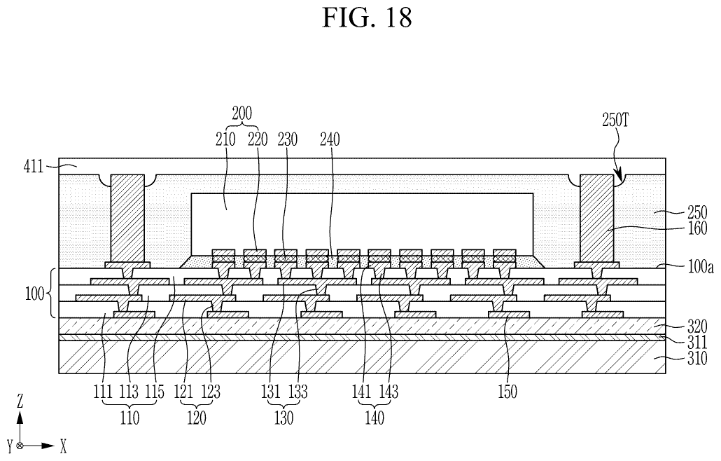

Next, referring to FIG. 18, a first upper redistribution insulation layer 411 may be formed on the semiconductor chip 200 and the molding member 250. The first upper redistribution insulation layer 411 may cover the upper surface of the molding member 250 and the upper surface of the conductive post 160. The first upper redistribution insulation layer 411 may be formed to fill the trench 250T of the molding member 250.

The shape of the first upper redistribution insulation layer 411 formed in the trench 250T of the molding member 250 may be substantially the same as that of the trench 250T of the molding member 250. For example, the first upper redistribution insulation layer 411 may have a first portion filling the trench 250T of the molding member 250. One side of the first portion may be in contact with the molding member 250 and may have a convex shape, and the other side of the first portion of the first upper redistribution insulation layer 411 in contact with the side of the conductive post 160 may have a straight line shape. In other words, the molding member 250 may have a concave shape to form the trench 250T, and the first portion of the first upper redistribution insulation layer 411 is formed within the trench 250T of the molding member 250.

Accordingly, the first upper redistribution insulation layer 411 positioned in a region where the edge portion positioned in the upper region of the molding member 250 and the conductive post 160 contact each other may have a curved shape.

The first upper redistribution insulation layer 411 may include or may be formed of a photo imageable dielectric (PID) insulating material which is process in a photolithography process. For example, the first upper redistribution insulation layer 411 may include or may be formed of photosensitive polyimide (PSPI).

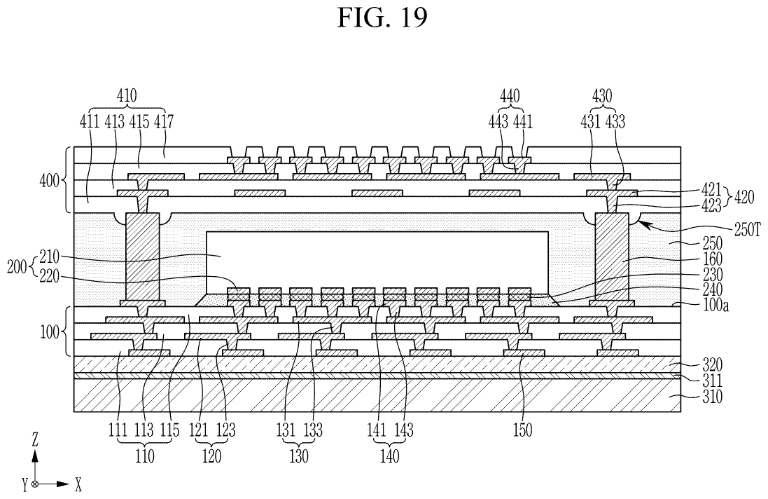

Next, referring to FIG. 19, an opening that exposes a portion of the upper surface of the conductive post 160 may be formed in the first upper redistribution insulation layer 411. The opening of the first upper redistribution insulation layer 411 may have a shape in which the width in the horizontal direction gradually narrows as it approaches the upper surface of the conductive post 160.

Next, a first upper conductive line pattern 421 and a first upper conductive via pattern 423 may be formed on the first upper redistribution insulation layer 411.

The first upper conductive via pattern 423 may be formed within the opening of the first upper redistribution insulation layer 411. The first upper conductive line pattern 421 may be formed on a portion of the upper surface of the first upper redistribution insulation layer 411. At least a part of the first upper conductive line pattern 421 may be connected to first upper conductive via pattern 423.

The first upper conductive line pattern 421 and the first upper conductive via pattern 423 may constitute a first upper redistribution pattern 420.

In some embodiments, after forming a seed layer (not shown) on the first upper redistribution insulation layer 411, a first upper conductive line pattern 421 and a first upper conductive via pattern 423 may be formed on the seed layer.

Specifically, a seed metal layer may be formed on the upper surface of the first upper redistribution insulation layer 411, the inner surface of the opening formed in the first upper redistribution insulation layer 411, and the upper surface of the conductive post 160 exposed by the opening of the first upper redistribution insulation layer 411. For example, the seed metal layer may be formed through a physical vapor deposition.

Then, after forming the seed metal layer, a photoresist pattern including an opening may be formed, and a plating process using the seed metal layer as a seed layer may be performed to form the first upper conductive line pattern 421 and the first upper conductive via pattern 423.

Next, the photoresist pattern may be removed, and a portion of the seed metal layer exposed by removing the photoresist pattern may be removed.

After the seed metal layer is removed, a seed layer positioned between the upper surface of the first upper redistribution insulation layer 411 and the first upper conductive line pattern 421, between the first upper conductive via pattern 423 and the inner surface of the opening of the first upper redistribution insulation layer 411, and between the first upper conductive via pattern 423 and the upper surface of the conductive post 160 may be formed.

Next, on the first upper redistribution insulation layer 411 and the first upper redistribution pattern 420, a second upper redistribution insulation layer 415, a second upper redistribution pattern 430, a third upper redistribution insulation layer 415, a third upper redistribution pattern 440, and a fourth upper redistribution insulation layer 417 may be sequentially formed.

The second upper conductive via pattern 433 may be formed in the opening of the second upper redistribution insulation layer 413 to be connected to at least a part of the second upper conductive line pattern 431 and may be formed on a part of the upper surface of the second upper redistribution insulation layer 413.

The second upper conductive line pattern 431 and the second upper conductive via pattern 433 may constitute the second upper redistribution pattern 430.

The third upper conductive via pattern 443 may be formed within the opening of the third upper redistribution insulation layer 415 to be connected to at least part of the third upper conductive line pattern 441 and may be formed on a portion of the upper surface of the third upper redistribution insulation layer 415.

The third upper conductive line pattern 441 and the third upper conductive via pattern 443 may constitute a third upper redistribution pattern 440.

The fourth upper redistribution insulation layer 417 may be formed on the third upper redistribution pattern 440. The fourth upper redistribution insulation layer 417 may include an opening that exposes a portion of the third upper conductive line pattern 441 of the third upper redistribution pattern 440.

Accordingly, a portion of the upper surface of the third upper conductive line pattern 441 may be exposed by the opening of the fourth upper redistribution insulation layer 417.

The method of forming the second upper redistribution insulation layer 413, the second upper redistribution pattern 430, the third upper redistribution insulation layer 415, and the third upper redistribution pattern 440 is substantially the same the method of forming the first upper redistribution insulation layer 411 and the first upper redistribution pattern 420 described above so that the description thereof is omitted.

Additionally, in some embodiments, after forming a seed layer (not shown) on the second upper redistribution insulation layer 413, a second upper conductive line pattern 431 and a second upper conductive via pattern 433 may be formed on the seed layer.

Subsequently, after forming a seed layer (not shown) on the third upper redistribution insulation layer 415, a third upper conductive line pattern 441 and a third upper conductive via pattern 443 may be formed on the seed layer.

The first to fourth upper redistribution insulation layers 411, 413, 415, and 417 may form the upper redistribution insulation layer 410, and the upper redistribution insulation layer 410 and the first to third upper redistribution patterns 420, 430, and 440 may form the upper redistribution substrate 400.

Although not shown in FIG. 19, in some embodiments, an upper semiconductor chip (not shown) may be mounted on the upper redistribution substrate 400 to be connected to at least some of the upper redistribution patterns 420, 430, and 440. A covering upper molding member (not shown) may be formed to cover the upper semiconductor chip mounted on the upper redistribution substrate 400.

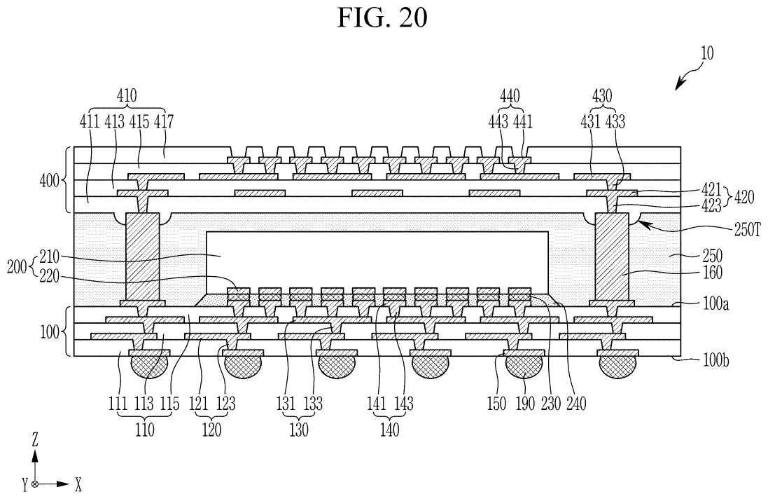

Next, referring further to FIG. 20 along with FIG. 19, the carrier substrate 310 to which the release film 311 is attached may be removed from the lower redistribution substrate 100. For example, to separate the carrier substrate 310, a laser may be irradiated or heat may be applied to the release film 311.

Next, the cover layer 320 may be removed to expose the bottom surface of the external electrode pad 150. For example, the cover layer 320 may be removed through an etching process.

Next, an external connection terminal 190 connected to the external electrode pad 150 may be attached on the second surface 100b of the lower redistribution substrate 100. The external connection terminal 190 may be, for example, at least one of a solder ball, a pillar, and a bump. However, the type of external connection terminal 190 is not limited to this and can be changed in various ways.

In the manufacturing method of the semiconductor package 10 according to an embodiment, some of the above-described processes may be omitted, or additional processes may be added.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A semiconductor package comprising:
a lower package substrate including a lower redistribution insulation layer and a lower redistribution pattern positioned within the lower redistribution insulation layer;
a semiconductor chip mounted on the lower package substrate;
a connection terminal positioned between the lower package substrate and the semiconductor chip, and connecting the semiconductor chip to the lower package substrate;
a molding member positioned on the lower package substrate and covering at least a portion of the semiconductor chip; and
a conductive post positioned within the molding member and connected to the lower redistribution pattern,
wherein the molding member and the conductive post define a trench,
wherein the trench includes a first inner surface recessed toward the lower package substrate from an upper surface of the molding member and a second inner surface corresponding to a side surface of the conductive post,
wherein the side surface of the conductive post extends beyond the first inner surface of the trench in a direction away from the lower package substrate, and
wherein the first inner surface of the molding member includes a first curved surface connecting the upper surface of the molding member to the side surface of the conductive post.

2. The semiconductor package of claim 1, further comprising:
an upper package substrate positioned on the upper surface of the molding member and including an upper redistribution insulation layer and an upper redistribution pattern positioned within the upper redistribution insulation layer,
wherein a first portion of the upper redistribution insulation layer of the upper package substrate is positioned within the trench.

3. The semiconductor package of claim 2,
wherein a width, in a first direction, between the first inner surface and the second inner surface of the trench of the molding member decreases in a direction toward the lower package substrate, and
where the first direction is parallel to the upper surface of the molding member.

4. The semiconductor package of claim 3,
wherein the first inner surface of the trench of the molding member has a concave shape.

5. The semiconductor package of claim 4,
wherein a curvature radius of the first inner surface of the trench is about 0.5 to 1.5 times a thickness of the first portion of the upper redistribution insulation layer.

6. The semiconductor package of claim 3,
wherein the first inner surface of the trench of the molding member has a convex shape.

7. The semiconductor package of claim 6,
wherein a curvature radius of the first inner surface of the trench is about 0.5 to 1.5 times a thickness of a second portion of the upper redistribution insulation layer, and
wherein the second portion of the upper redistribution insulation layer is positioned on the upper surface of the molding member and the first portion of the upper redistribution insulation layer.

8. The semiconductor package of claim 3,
wherein an edge portion of the upper surface of the lower redistribution pattern which is directly connected to the conductive post includes a curved surface.

9. The semiconductor package of claim 2,
wherein the second inner surface of the trench of the molding member includes a second curved surface.

10. A semiconductor package comprising:
a lower package substrate including a lower redistribution insulation layer and a lower redistribution pattern positioned within the lower redistribution insulation layer;
a semiconductor chip mounted on the lower package substrate;
a connection terminal positioned between the lower package substrate and the semiconductor chip, and connecting the semiconductor chip to the lower package substrate;
a molding member positioned on the lower package substrate and covering at least a portion of the semiconductor chip;
a conductive post positioned within the molding member and connected to the lower redistribution pattern; and
an upper package substrate positioned on an upper surface of the molding member and including an upper redistribution insulation layer and an upper redistribution pattern positioned within the upper redistribution insulation layer,
wherein the molding member and the conductive post define a trench,
wherein the trench includes a first inner surface recessed toward a bottom surface of the molding member from the upper surface of the molding member and a second inner surface corresponding to a side surface of the conductive post, and
wherein the first inner surface of the trench has one of a convex shape and a concave shape.

11. The semiconductor package of claim 10,
wherein the second inner surface of the trench of the molding member has a straight line shape.

12. The semiconductor package of claim 11,
wherein a first portion of the upper redistribution insulation layer of the upper package substrate is positioned within the trench of the molding member, and
wherein the first portion of the upper redistribution insulation layer covers the side surface of the conductive post.

13. The semiconductor package of claim 12,
wherein a width, in a first direction, of the first portion of the upper redistribution insulation layer decreases in a direction toward the lower package substrate, and
wherein the first direction is parallel to the upper surface of the molding member.

14. The semiconductor package of claim 12,
wherein the upper surface of the molding member is positioned at substantially the same level as an upper surface of the conductive post, and
wherein the upper surface of the molding member and the upper surface of the conductive post are positioned at a higher level than an upper surface of the semiconductor chip.

15. The semiconductor package of claim 14,
wherein the trench of the molding member is positioned between the upper surface of the molding member and the upper surface of the semiconductor chip.

16. The semiconductor package of claim 12,
wherein the conductive post includes copper (Cu), and
wherein the molding member is an epoxy mold compound (EMC).

17. The semiconductor package of claim 10,
wherein the conductive post is positioned further within the trench of the molding member.

18. A semiconductor package comprising:
a lower package substrate including a lower redistribution insulation layer and a lower redistribution pattern positioned within the lower redistribution insulation layer;
a semiconductor chip mounted on the lower package substrate;
a connection terminal positioned between the lower package substrate and the semiconductor chip, and connecting the semiconductor chip to the lower package substrate;
a molding member positioned on the lower package substrate and covering at least a portion of the semiconductor chip;
a conductive post positioned within the molding member and connected to the lower redistribution pattern; and
an upper package substrate positioned on the molding member and including an upper redistribution insulation layer and an upper redistribution pattern positioned within the upper redistribution insulation layer,
wherein the conductive post includes:
a first part positioned on the lower redistribution pattern; and
a second part positioned on the first part and contacting the upper redistribution insulation layer of the upper package substrate,
wherein a width of the first part and a width of the second part are different from each other, and
wherein an upper region of the second part includes a curved surface.

19. The semiconductor package of claim 18,
wherein the width of the first part of the conductive post is greater than the width of the second part.

20. The semiconductor package of claim 18,
wherein the width of the first part of the conductive post decreases in a direction toward the lower package substrate.
